(19) United States
(12) Patent Application Publication
(10) Pub. No.: US 2025/0003770 A1
(43) Pub. Date: Jan. 2, 2025

(54) MAGNETIC SENSOR, POSITION DETECTION DEVICE, AND LENS MODULE

(71) Applicant: TDK Corporation, Tokyo (JP)

(72) Inventors: Takehiro ISODA, Tokyo (JP); Takafumi KOBAYASHI, Tokyo (JP)

(73) Assignee: TDK Corporation, Tokyo (JP)

(21) Appl. No.: 18/751,399

(22) Filed: Jun. 24, 2024

(30) Foreign Application Priority Data
Jun. 30, 2023 (JP) 2023-108800

(51) Int. Cl. G01D 5/16; G02B 7/08

(52) U.S. Cl. CPC G01D 5/16; G02B 7/08

(57) ABSTRACT

A magnetic sensor includes a soft magnetic structure including at least one yoke, and magnetoresistive (MR) elements configured to detect a magnetic field generated by the at least one yoke, the MR elements being adjacent to the at least one yoke in a transverse direction of the at least one yoke. The soft magnetic structure further includes at least one additional magnetic body arranged next to the at least one yoke in a longitudinal direction of the at least one yoke and located off the at least one yoke in an orthogonal direction orthogonal to the longitudinal direction.

### CROSS REFERENCE TO RELATED APPLICATIONS

This application claims the benefit of Japanese Priority Patent Application No. 2023-108800 filed on Jun. 30, 2023, the entire contents of which are incorporated herein by reference.

### BACKGROUND

The technology relates to a magnetic sensor that includes at least one yoke and a magnetic detection element and is configured to detect a magnetic field in a predetermined direction, and a position detection device and a lens module each including the magnetic sensor.

Magnetic sensors have been used for a variety of applications. Examples of known magnetic sensors include one that uses a spin-valve magnetoresistive element provided on a substrate. The spin-valve magnetoresistive element includes a magnetization pinned layer having a magnetization whose direction is fixed, a free layer having a magnetization whose direction is variable depending on the direction of an applied magnetic field, and a gap layer located between the magnetization pinned layer and the free layer. In many cases, the spin-valve magnetoresistive element provided on a substrate is configured to have sensitivity to a magnetic field in a direction parallel to the surface of the substrate.

On the other hand, a system including a magnetic sensor may be intended to detect a magnetic field in a direction perpendicular to the surface of a substrate by using a magnetoresistive element provided on the substrate. As a magnetic sensor to achieve this, a magnetic sensor including a yoke formed of a soft magnetic body has been known. The yoke converts a magnetic field in a direction perpendicular to the surface of the substrate into a magnetic field in a direction parallel to the surface of the substrate, and supplies the resulting magnetic field to the magnetoresistive element. An example of such a magnetic sensor is described in US 2022/0260654 A1.

US 2022/0260654 A1 discloses a magnetic sensor including a magnetic field conversion unit, a plurality of magnetoresistive elements, and wiring portions. The magnetic field conversion unit includes a plurality of yokes. Each of the plurality of yokes has a shape long in one direction, and receives an input magnetic field in a direction perpendicular to the surface of the substrate and generates an output magnetic field in a direction parallel to the surface of the substrate. The plurality of magnetoresistive elements are disposed in groups of two or more on both sides of each of the plurality yokes.

Aside from the input magnetic field, another magnetic field in a direction parallel to the surface of the substrate is applied to each of the plurality of yokes in some cases. In such a case, each of the plurality of yokes is magnetized in a given direction depending on the direction of the other magnetic field. If the direction of the other magnetic field changes, the magnetization direction of each of the plurality of yokes changes, and as a result, the magnetization direction of the free layer in each of the plurality of magnetoresistive elements changes. There has thus been a problem of a change in characteristics obtained from the output of the magnetic sensor under a continuously changing magnetic field, such as linearity and hysteresis.

### SUMMARY

A magnetic sensor according to one embodiment of the technology includes: a soft magnetic structure including at least one yoke having a shape long in one direction; and a magnetic detection element configured to detect a magnetic field generated by the at least one yoke, the magnetic detection element being adjacent to the at least one yoke in a transverse direction of the at least one yoke. The soft magnetic structure further includes at least one additional magnetic body arranged next to the at least one yoke in a longitudinal direction of the at least one yoke and located off the at least one yoke in an orthogonal direction orthogonal to the longitudinal direction.

A position detection device according to one embodiment of the technology includes: the magnetic sensor according to one embodiment of the technology; and a magnetic field generator configured to have a magnetization in a direction parallel to the orthogonal direction and generate a magnetic field to be applied to the at least one yoke. The magnetic sensor and the magnetic field generator are configured to change their relative position in the orthogonal direction and so that a strength of the magnetic field changes with a change in the relative position.

A lens module according to one embodiment of the technology includes: a lens configured to change in position; the magnetic sensor according to one embodiment of the technology; and a magnetic field generator configured to have a magnetization in a direction parallel to the orthogonal direction and generate a magnetic field to be applied to the at least one yoke. The magnetic sensor and the magnetic field generator are configured so that a strength of the magnetic field changes with a change in the position of the lens.

Other and further objects, features, and advantages of the technology will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the technology.

FIG. 2 is a circuit diagram showing a circuit configuration of the magnetic sensor according to the first example embodiment of the technology.

FIG. 3 is a sectional view showing a part of a section at the position indicated by line 3-3 in FIG. 1.

FIG. 4 is a sectional view showing a part of a section at the position indicated by line 4-4 in FIG. 1.

FIG. 5 is a side view showing a part of the magnetic sensor according to the first example embodiment of the technology.

FIG. 6 is a perspective view showing a plurality of yokes and a plurality of additional magnetic bodies of the first example embodiment of the technology.

FIG. 7 is a perspective view showing a part of a wiring portion and magnetoresistive elements of the first example embodiment of the technology.

FIG. 8 is a perspective view showing a magnetoresistive element of the first example embodiment of the technology.

FIG. 9 is a front view showing the magnetic sensor and a magnetic field generator according to the first example embodiment of the technology.

FIG. 10 is a perspective view showing a lens module according to the first example embodiment of the technology.

FIG. 11 is an explanatory diagram schematically showing an interior of the lens module according to the first example embodiment of the technology.

FIG. 12 is a perspective view showing a position detection device and a driving device according to the first example embodiment of the technology.

FIG. 13 is a perspective view showing a plurality of coils of the driving device of the first example embodiment of the technology.

FIG. 14 is a perspective view showing a plurality of yokes and a plurality of additional magnetic bodies of a second example embodiment of the technology.

FIG. 15 is a perspective view showing a plurality of yokes and a plurality of additional magnetic bodies of a third example embodiment of the technology.

FIG. 16 is a plan view showing a magnetic sensor according to a fourth example embodiment of the technology.

FIG. 17 is a side view showing a soft magnetic structure of the fourth example embodiment of the technology.

FIG. 18 is a side view showing a first modification of the soft magnetic structure of the fourth example embodiment of the technology.

FIG. 19 is a side view showing a second modification of the soft magnetic structure of the fourth example embodiment of the technology.

FIG. 20 is a perspective view showing a plurality of yokes and a plurality of additional magnetic bodies of a fifth example embodiment of the technology.

FIG. 21 is a side view showing a soft magnetic structure of a sixth example embodiment of the technology.

FIG. 22 is a plan view showing a plurality of yokes and a plurality of additional magnetic bodies of the sixth example embodiment of the technology.

FIG. 23 is a plan view showing a plurality of yokes and a plurality of additional magnetic bodies of a seventh example embodiment of the technology.

FIG. 24 is a side view showing a soft magnetic structure of an eighth example embodiment of the technology.

FIG. 25 is a side view showing a soft magnetic structure of a ninth example embodiment of the technology.

FIG. 26 is a plan view showing a plurality of yokes and a plurality of additional magnetic bodies of a tenth example embodiment of the technology.

FIG. 27 is a side view showing a soft magnetic structure of an eleventh example embodiment of the technology.

FIG. 28 is a side view showing a soft magnetic structure of a twelfth example embodiment of the technology.

FIG. 29 is a side view showing a soft magnetic structure of a thirteenth example embodiment of the technology.

### DETAILED DESCRIPTION

An object of the technology is to provide a magnetic sensor capable of preventing a change in its output characteristics due to at least one yoke, and a position detection device and a lens module each including the magnetic sensor.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

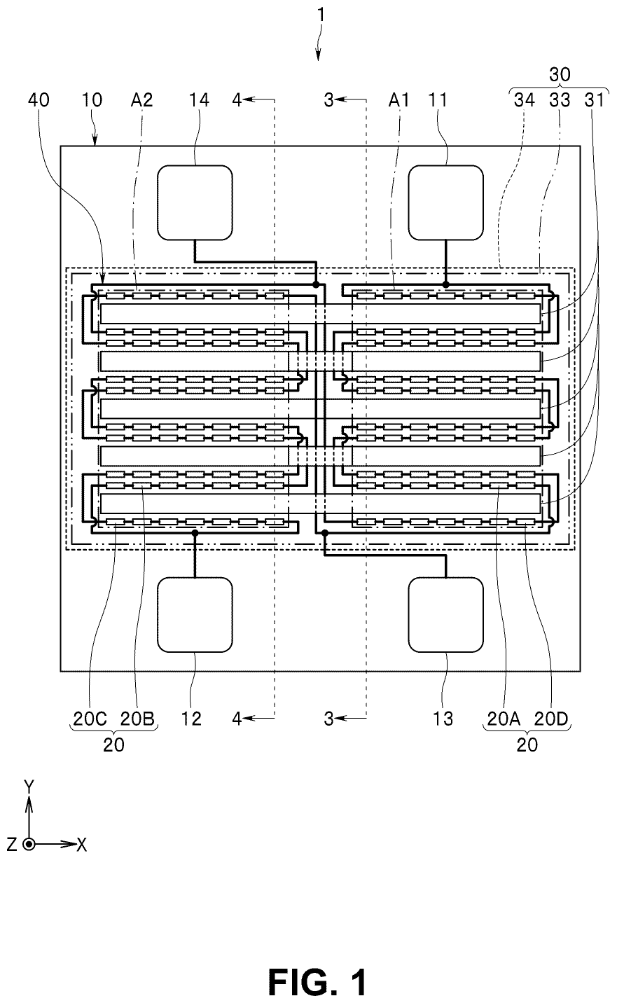

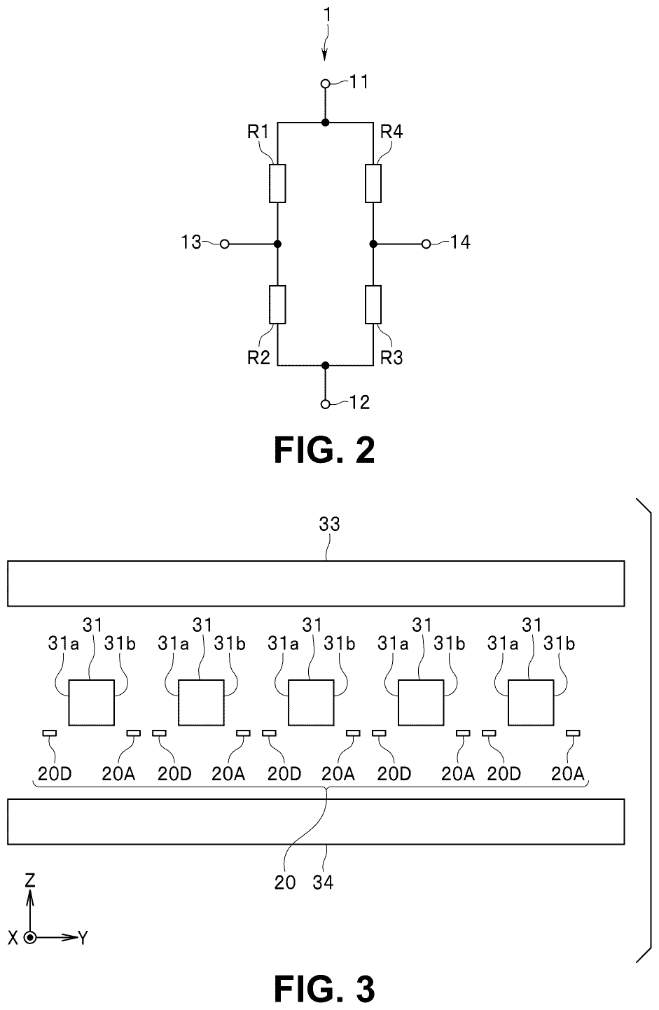

A schematic configuration of a magnetic sensor according to a first example embodiment of the technology will initially be described with reference to FIGS. 1 and 2. FIG. 1 is a plan view showing a magnetic sensor 1 according to the present example embodiment. FIG. 2 is a circuit diagram showing a circuit configuration of the magnetic sensor 1 according to the present example embodiment.

The magnetic sensor 1 according to the present example embodiment includes a power supply terminal 11, a ground terminal 12, a first output terminal 13, a second output terminal 14, a first resistor section R1, a second resistor section R2, a third resistor section R3, and a fourth resistor section R4. Each of the first to fourth resistor sections R1 to R4 includes a plurality of magnetic detection elements.

As shown in FIG. 2, the first resistor section R1 is provided between the power supply terminal 11 and the first output terminal 13 in circuit configuration. The second resistor section R2 is provided between the ground terminal 12 and the first output terminal 13 in the circuit configuration. The third resistor section R3 is provided between the ground terminal 12 and the second output terminal 14 in the circuit configuration. The fourth resistor section R4 is provided between the power supply terminal 11 and the second output terminal 14 in the circuit configuration. In the present application, the expression “in (the) circuit configuration” is used to indicate a layout in a circuit diagram and not a layout in a physical configuration.

A voltage or current of predetermined magnitude is applied to the power supply terminal 11. The ground terminal 12 is grounded.

The magnetic sensor 1 further includes a soft magnetic structure 30 formed of a soft magnetic material, a substrate 10, and a not-shown insulating layer. The power supply terminal 11, the ground terminal 12, the first and second output terminals 13 and 14, the first to fourth resistor sections R1 to R4, and the soft magnetic structure 30 are disposed on the substrate 10. The first to fourth resistor sections R1 to R4 and at least a part of the soft magnetic structure 30 are embedded in the not-shown insulating layer formed on the substrate 10.

The soft magnetic structure 30 includes at least one yoke, at least one additional magnetic body, and at least one shield. The at least one yoke has a shape long in one direction. As employed herein, the longitudinal direction of the at least one yoke will be referred to simply as a longitudinal direction. The transverse direction of the at least one yoke will be referred to simply as a transverse direction. The at least one additional magnetic body is arranged next to the at least one yoke in the longitudinal direction. The at least one additional magnetic body is also located off the at least one yoke in an orthogonal direction orthogonal to the longitudinal direction. As employed herein, being “located off” covers both cases where the entirety of the at least one additional magnetic body is off the at least one yoke and where a part of the at least one additional magnetic body is off the at least one yoke.

The at least one shield is located off the at least one yoke in a direction orthogonal to the transverse and longitudinal directions. As will be described below, in the present example embodiment, the at least one shield is also located off the at least one additional magnetic body in the direction orthogonal to the transverse and longitudinal directions.

Each of the plurality of magnetic detection elements is adjacent to the at least one yoke in the transverse direction. The at least one yoke is configured to receive a magnetic field to be detected by the magnetic sensor 1 and generate a magnetic field to be applied to each of the plurality of magnetic detection elements. The magnetic field to be detected includes a component perpendicular to a surface of the substrate 10. The magnetic field generated by the at least one yoke includes a component parallel to the surface of the substrate 10. Each of the plurality of magnetic detection elements is configured to have sensitivity to a magnetic field in a direction parallel to the surface of the substrate 10 so that the magnetic field generated by the at least one yoke can be detected.

In particular, in the present example embodiment, the magnetic sensor 1 includes a plurality of magnetoresistive elements (hereinafter, referred to as MR elements) 20 as the plurality of magnetic detection elements. The magnetic sensor 1 further includes wiring portions 40 for electrically connecting the plurality of MR elements 20.

Now, we define X, Y, and Z directions as shown in FIG. 1. The X, Y, and Z directions are orthogonal to one another. The opposite directions to the X, Y, and Z directions will be referred to as −X, −Y, and −Z directions, respectively. In particular, in the example embodiment, a direction perpendicular to the surface of the substrate 10 is referred to as the Z direction.

As used herein, the term “above” refers to positions located forward of a reference position in the Z direction, and “below” refers to positions located on a side of the reference position opposite to “above”. Concerning the components of the magnetic sensor 1, the term “top surface” refers to the surface located at the end in the Z direction, and the term “bottom surface” refers to the surface located at the end in the −Z direction. The power supply terminal 11, the ground terminal 12, the first and second output terminals 13 and 14, the first to fourth resistor sections R1 to R4, and the soft magnetic structure 30 may be located above the top surface of the substrate 10, for example. The expression “viewed in the Z direction” means that a target is viewed from a position away from the target in the Z direction.

As employed herein, an area for laying out the plurality of MR elements 20 is referred to as an element layout area. The element layout area is a flat area defined to overlap the substrate 10 when viewed in the Z direction. In particular, in the present example embodiment, the element layout area includes two areas A1 and A2. The area A2 is located forward of the area A1 in the −X direction. Each of the plurality of MR elements 20 is disposed in the area A1 or the area A2 when viewed in the Z direction. In the following description, a positional relationship between a plurality of components of the magnetic sensor 1 and the areas A1 and A2 refer to that viewed in the Z direction.

In the present example embodiment, the power supply terminal 11 and the first output terminal 13 are located with the area A1 therebetween. The ground terminal 12 and the second output terminal 14 are located with the area A2 therebetween. Among the plurality of MR elements 20, a plurality of elements constituting the first and fourth resistor sections R1 and R4 are disposed in the area A1. Among the plurality of MR elements 20, a plurality of elements constituting the second and third resistor sections R2 and R3 are disposed in the area A2.

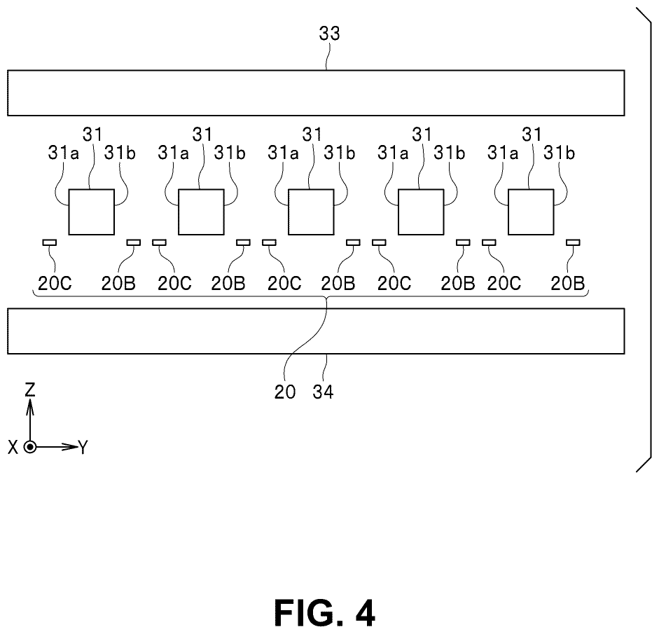

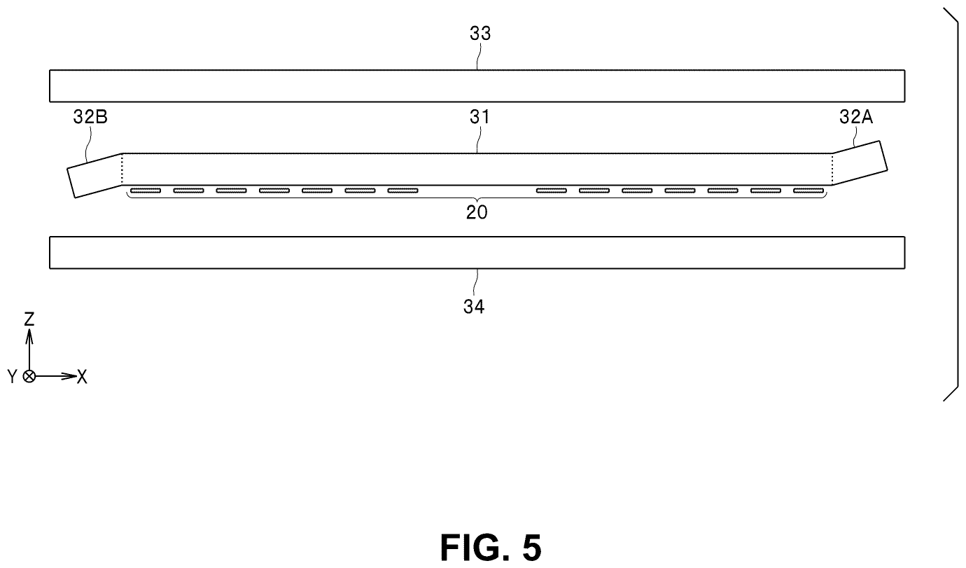

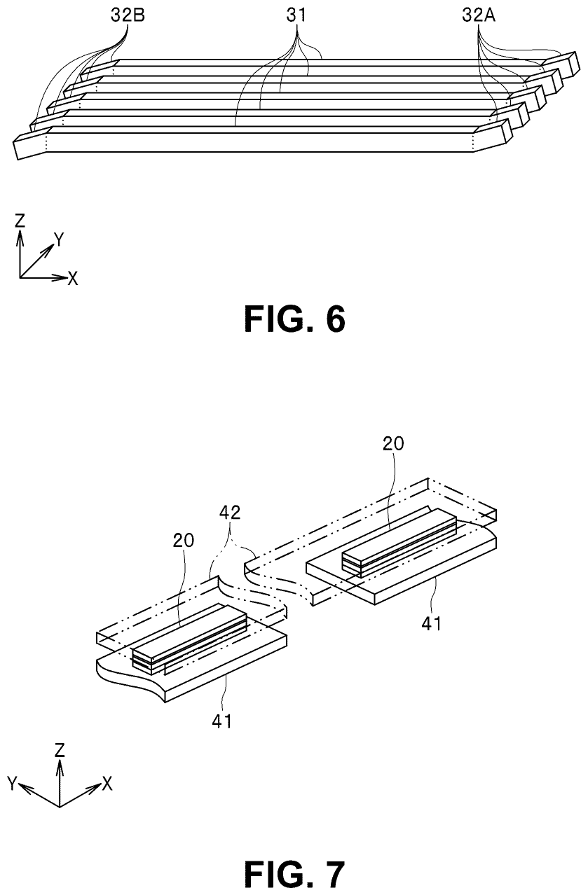

Next, the layout of the plurality of MR elements 20 and the configuration of the soft magnetic structure 30 will be described in detail with reference to FIGS. 1 and 3 to 6. FIG. 3 is a sectional view showing a part of a section at the position indicated by line 3-3 in FIG. 1. FIG. 4 is a sectional view showing a part of a section at the position indicated by line 4-4 in FIG. 1. FIG. 5 is a side view showing a part of the magnetic sensor 1 viewed in the −Y direction in FIG. 1. FIG. 6 is a perspective view showing a plurality of yokes and a plurality of additional magnetic bodies.

In the present example embodiment, the soft magnetic structure 30 includes a plurality of yokes 31. Each of the plurality of yokes 31 has a rectangular solid shape extending in a direction parallel to the X direction. In particular, in the present example embodiment, each of the plurality of yokes 31 extends across the areas A1 and A2. The plurality of yokes 31 are arranged in the Y direction. The direction parallel to the X direction corresponds to the “longitudinal direction of the at least one yoke”. A direction parallel to the Y direction corresponds to the “transverse direction of the at least one yoke”.

The plurality of MR elements 20 are located forward of the plurality of yokes 31 in the −Z direction. Each of the plurality of MR elements 20 is adjacent to a corresponding yoke 31 in the direction parallel to the Y direction. The positional relationship between the plurality of MR elements 20 and the plurality of yokes 31 is not limited to the example shown in FIGS. 3 to 5. For example, the plurality of MR elements 20 may be located forward of the plurality of yokes 31 in the Z direction.

Each of the plurality of yokes 31 has a first end face 31a located at the end in the −Y direction, and a second end face 31b located at the end in the Y direction. Each of the plurality of MR elements 20 is located near the first end face 31a or the second end face 31b of the corresponding yoke 31, at a predetermined distance from the first end face 31a or the second end face 31b.

Among the plurality of MR elements 20, each of a plurality of elements constituting the first resistor section R1 will be denoted by the reference numeral 20A. Each of a plurality of elements constituting the fourth resistor section R4 will be denoted by the reference numeral 20D. The plurality of elements 20A and the plurality of elements 20D may be both connected in series. As shown in FIGS. 1 and 3, the plurality of elements 20A are arranged in groups of two or more along the second end face 31b of each of the plurality of yokes 31 in the area A1. As shown in FIGS. 1 and 3, the plurality of elements 20D are arranged in groups of two or more along the first end face 31a of each of the plurality of yokes 31 in the area A1.

Among the plurality of MR elements 20, each of a plurality of elements constituting the second resistor section R2 will be denoted by the reference numeral 20B. Each of a plurality of elements constituting the third resistor section R3 will be denoted by the reference numeral 20C. The plurality of elements 20B and the plurality of elements 20C may be both connected in series. As shown in FIGS. 1 and 4, the plurality of elements 20B are arranged in groups of two or more along the second end face 31b of each of the plurality of yokes 31 in the area A2. As shown in FIGS. 1 and 4, the plurality of elements 20C are arranged in groups of two or more along the first end face 31a of each of the plurality of yokes 31 in the area A2.

Each of the plurality of yokes 31 is configured to receive an input magnetic field including an input magnetic field component in a direction parallel to the Z direction and generate an output magnetic field. The output magnetic field includes an output magnetic field component in the direction parallel to the Y direction. The output magnetic field component changes depending on the input magnetic field component. In the present example embodiment, the output magnetic field corresponds to the “magnetic field generated by the at least one yoke” of the technology. Each of the plurality of MR elements 20 is configured to change in resistance depending on the direction and strength of the output magnetic field component.

In the present application, an “input magnetic field component” refers to a magnetic field component at a position away from a yoke 31. If it is assumed that no yoke 31 exists, the “input magnetic field component” is substantially the same as the magnetic field component near the position for the yoke 31 to be located at. In the present application, an “output magnetic field component” refers to a magnetic field component at a location near a yoke 31 and where there is an MR element 20. The presence of the yoke 31 makes the “output magnetic field component” different from the magnetic field component without the yoke 31 (input magnetic field component).

The soft magnetic structure 30 may further include a plurality of first additional magnetic bodies 32A and a plurality of second additional magnetic bodies 32B. As shown in FIGS. 5 and 6, each of the plurality of first additional magnetic field bodies 32A and each of the plurality of second additional magnetic bodies 32B are arranged next to a corresponding yoke 31 in the direction parallel to the X direction. In FIG. 1, the plurality of first additional magnetic bodies 32A and the plurality of second additional magnetic bodies 32B are omitted.

In particular, in the present example embodiment, each of the plurality of first additional magnetic bodies 32A is connected to the end of a corresponding yoke 31 in the X direction. Each of the plurality of second additional magnetic bodies 32B is connected to the end of a corresponding yoke 31 in the −X direction. Each yoke 31 is connected to one first additional magnetic body 32A and one second additional magnetic body 32B. The first additional magnetic body 32A and the second additional magnetic body 32B are located so that the yoke 31 is interposed between the first additional magnetic body 32A and the second additional magnetic body 32B. In FIGS. 5 and 6, the border between the yoke 31 and the first additional magnetic body 32A and the border between the yoke 31 and the second additional magnetic body 32B are both shown in dotted lines. The plurality of yokes 31, the plurality of first additional magnetic bodies 32A, and the plurality of second additional magnetic bodies 32B may be formed of the same magnetic material.

As shown in FIG. 5, each of the plurality of first additional magnetic bodies 32A and each of the plurality of second additional magnetic bodies 32B are located off the corresponding yoke 31 in the direction parallel to the Z direction. In particular, in the present example embodiment, each of the plurality of first additional magnetic bodies 32A extends from the end of the corresponding yoke 31 obliquely in the Z direction so that a part of the first additional magnetic body 32A is off the corresponding yoke 31 in the Z direction. Each of the plurality of second additional magnetic bodies 32B extends from the end of the corresponding yoke 31 obliquely in the −Z direction so that a part of the second additional magnetic body 32B is off the corresponding yoke 31 in the −Z direction.

As shown in FIG. 6, the plurality of first additional magnetic bodies 32A are arranged in the direction parallel to the Y direction. The plurality of second additional magnetic bodies 32B are arranged in the direction parallel to the Y direction.

As shown in FIG. 5, each of the plurality of MR elements 20 does not need to be adjacent to the first and second additional magnetic bodies 32A and 32B in the direction parallel to the Y direction.

Suppose that the number of yokes 31 is N (N is an integer greater than or equal to 2). The sum of the number of first additional magnetic bodies 32A and the number of second additional magnetic bodies 32B is 2N.

As shown in FIGS. 3 to 5, the soft magnetic structure 30 further includes two shields 33 and 34. Each of the two shields 33 and 34 covers the plurality of MR elements 20, the plurality of yokes 31, the plurality of first additional magnetic bodies 32A, and the plurality of second additional magnetic bodies 32B when viewed in the Z direction. The shield 33 is located forward of the plurality of MR elements 20, the plurality of yokes 31, the plurality of first additional magnetic bodies 32A, and the plurality of second additional magnetic bodies 32B in the Z direction. The shield 34 is located forward of the plurality of MR elements 20, the plurality of yokes 31, the plurality of first additional magnetic bodies 32A, and the plurality of second additional magnetic bodies 32B in the −Z direction. The planar shape (shape viewed in the Z direction) of each of the shields 33 and 34 is rectangular, for example.

The center positions of the yokes 31 in the direction parallel to the X direction, the center position of the shield 33 in the direction parallel to the X direction, and the center position of the shield 34 in the direction parallel to the X direction are the same or substantially the same in the direction parallel to the X direction.

Next, the wiring portions 40 will be described with reference to FIGS. 1 and 7. FIG. 7 is a perspective view showing a part of a wiring portion 40 and MR elements 20. The wiring portion 40 includes a plurality of lower electrodes 41 and a plurality of upper electrodes 42 for electrically connecting a plurality of MR elements 20 arranged in a row in the direction parallel to the X direction. The plurality of MR elements 20 are disposed on the plurality of lower electrodes 41. The plurality of upper electrodes 42 are disposed on the plurality of MR elements 20.

The connections between the plurality of MR elements 20, the lower electrodes 41, and the upper electrodes 42 will now be described. Each of the plurality of lower electrodes 41 has a long slender shape in the X direction. There is a gap between two lower electrodes 41 adjacent in the X direction. Each of the MR elements 20 is located on the top surface of each lower electrode 41, near both ends in the X direction. Each of the plurality of upper electrodes 42 electrically connects two adjacent MR elements 20 disposed on two lower electrodes 41 adjacent in the X direction. In such a manner, the plurality of MR elements 20 arranged in a row are connected in series.

The wiring portions 40 further include a plurality of connection electrodes. In each of the first to fourth resistor sections R1 to R4, a plurality of connection electrodes electrically connect a plurality of lower electrodes 41 or a plurality of upper electrodes 42 so that a plurality of groups of MR elements 20 arranged in a row are connected in series.

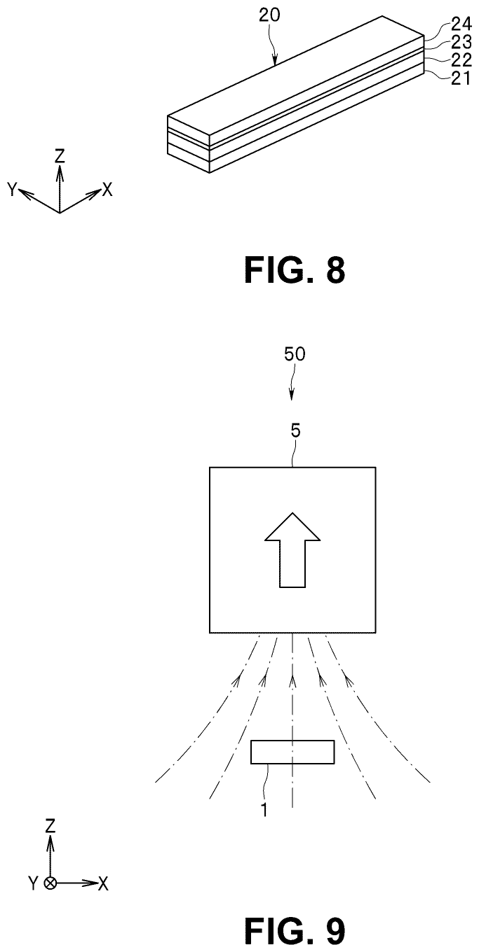

Next, a configuration of the MR element 20 will be described with reference to FIG. 8. FIG. 8 is a perspective view showing the MR element 20. The MR element 20 is a spin-valve MR element. The MR element 20 includes a magnetization pinned layer 22 having a magnetization whose direction is fixed, a free layer 24 having a magnetization whose direction is variable depending on the direction of an applied magnetic field, and a gap layer 23 located between the magnetization pinned layer 22 and the free layer 24. The MR element 20 may be a tunneling magnetoresistive (TMR) element or a giant magnetoresistive (GMR) element. In the TMR element, the gap layer 23 is a tunnel barrier layer. In the GMR element, the gap layer 23 is a nonmagnetic conductive layer. The resistance of the MR element 20 changes with the angle that the magnetization direction of the free layer 24 forms with respect to the magnetization direction of the magnetization pinned layer 22. The resistance of the MR elements 20 is at its minimum value when the foregoing angle is 0°, and at its maximum value when the foregoing angle is 180°. In each MR element 20, the free layer 24 has a shape anisotropy such that the direction of its magnetization easy axis is orthogonal to the magnetization direction of the magnetization pinned layer 22.

The MR element 20 further includes an antiferromagnetic layer 21. The antiferromagnetic layer 21, the magnetization pinned layer 22, the gap layer 23, and the free layer 24 are stacked in this order in the Z direction. The antiferromagnetic layer 21 is formed of an antiferromagnetic material, and is in exchange coupling with the magnetization pinned layer 22 to thereby pin the magnetization direction of the magnetization pinned layer 22. The magnetization pinned layer 22 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 22 is the self-pinned layer, the antiferromagnetic layer 21 may be omitted.

It should be appreciated that the layers 21 to 24 of each MR element 20 may be stacked in the reverse order to that shown in FIG. 8.

In the present example embodiment, the magnetization directions of the magnetization pinned layers 22 are parallel to the Y direction. In the present example embodiment, the magnetization direction of the magnetization pinned layer 22 in each of the plurality of MR elements 20 of the first resistor section R1, i.e., the plurality of elements 20A and the magnetization direction of the magnetization pinned layer 22 in each of the plurality of MR elements 20 of the second resistor section R2, i.e., the plurality of elements 20B are opposite to each other. The magnetization direction of the magnetization pinned layer 22 in each of the plurality of MR elements 20 of the third resistor section R3, i.e., the plurality of elements 20C is the same as that of the magnetization pinned layer 22 in each of the plurality of elements 20B. The magnetization direction of the magnetization pinned layer 22 in each of the plurality of MR elements 20 of the fourth resistor section R4, i.e., the plurality of elements 20D is the same as that of the magnetization pinned layer 22 in each of the plurality of elements 20A.

In particular, in the present example embodiment, the magnetization direction of the magnetization pinned layer 22 in each of the plurality of elements 20A and the plurality of elements 20D is the −Y direction. The magnetization direction of the magnetization pinned layer 22 in each of the plurality of elements 20B and the plurality of elements 20C is the Y direction.

In the present example embodiment, each of the plurality of MR elements 20 has a shape long in the direction parallel to the X direction. The free layer 24 in each of the plurality of MR elements 20 thus has a shape anisotropy such that the direction of its magnetization easy axis is parallel to the X direction. When there is no magnetic field applied, the magnetization direction of the free layer 24 is parallel to the X direction. When there is an output magnetic field component, the magnetization direction of the free layer 24 varies depending on the direction and strength of the output magnetic field component. The angle that the magnetization direction of the free layer 24 forms with the magnetization direction of the magnetization pinned layer 22 thus changes depending on the direction and strength of the output magnetic field component that each of the plurality of MR elements 20 receives. Each of the plurality of MR elements 20 thus has a resistance corresponding to the output magnetic field component.

In the present example embodiment, the direction of the output magnetic field component that the plurality of elements 20B receive is the same as the direction of the output magnetic field component that the plurality of elements 20A receive. On the other hand, the direction of the output magnetic field component that the plurality of elements 20C receive and the direction of the output magnetic field component that the plurality of elements 20D receive are opposite to the direction of the output magnetic field component that the plurality of elements 20A receive.

Next, operation of the magnetic sensor 1 according to the present example embodiment will be described. In the present example embodiment, the magnetic field to be detected by the magnetic sensor 1 includes one of the components in the Z direction and the −Z direction, but does not include the other. A case where the magnetic field to be detected by the magnetic sensor 1 includes the component in the Z direction but does not include the component in the −Z direction will be described as an example. In such a case, the direction of the input magnetic field component of the input magnetic field input to each of the plurality of yokes 31 is the Z direction.

The following description will be given on the assumption that the input magnetic field consists only of an input magnetic field component in the Z direction. When there is no input magnetic field component and, as a result, no output magnetic field component, the magnetization direction of the free layer 24 in each of the plurality of MR elements 20 is parallel to the X direction. When there is an input magnetic field component in the Z direction, the direction of the output magnetic field component that the plurality of MR elements 20 constituting the first and second resistor sections R1 and R2 receive is the −Y direction. The direction of the output magnetic field component that the plurality of MR elements 20 constituting the third and fourth resistor sections R3 and R4 receive is the Y direction. In such a case, the magnetization direction of the free layer 24 in each of the plurality of MR elements 20 constituting the first and second resistor sections R1 and R2 tilts from the direction parallel to the X direction toward the −Y direction. The magnetization direction of the free layer 24 in each of the plurality of MR elements 20 constituting the third and fourth resistor sections R3 and R4 tilts from the direction parallel to the X direction toward the Y direction. As a result, the resistance of each of the plurality of MR elements 20 constituting the first and third resistor sections R1 and R3 decreases and the resistance of each of the first and third resistor sections R1 and R3 decreases as well, compared to when there is no output magnetic field component. Moreover, the resistances of the plurality of MR elements 20 constituting the second and fourth resistor sections R2 and R4 increase and the resistances of the second and fourth resistor sections R2 and R4 increase as well, compared to when there is no output magnetic field component.

The amount of change in the resistance of an MR element 20 depends on the strength of the output magnetic field component that the MR element 20 receives. As the strength of the output magnetic field component increases, the resistance of the MR element 20 changes so that the amount of increase or the amount of decrease increases. As the strength of the output magnetic field component decreases, the resistance of the MR element 20 changes so that the amount of increase or the amount of decrease decreases. The strength of the output magnetic field component depends on the strength of the input magnetic field component.

As the strength of the input magnetic field component changes, the resistances of the first to fourth resistor sections R1 to R4 thus change so that the resistances of the first and third resistor sections R1 and R3 increase and the resistances of the second and fourth resistor sections R2 and R4 decrease. As a result, a potential difference between the first output terminal 13 and the second output terminal 14 shown in FIG. 2 changes. The magnetic sensor 1 generates a detection signal that depends on the potential difference between the first output terminal 13 and the second output terminal 14. The detection signal has a correspondence with the strength of the input magnetic field component.

Next, the effects of the magnetic sensor 1 according to the present example embodiment will be described. When the magnetic sensor 1 is in use, the magnetic field to be detected is always applied to the magnetic sensor 1. As described above, if the magnetic field to be detected includes a component in the Z direction and not a component in the −Z direction, an external magnetic field in the Z direction is applied to the plurality of yokes 31, the plurality of first additional magnetic bodies 32A, and the plurality of second additional magnetic bodies 32B.

FIG. 5 shows a yoke 31, and a first additional magnetic body 32A and a second additional magnetic body 32B both connected to the yoke 31. Now, focus attention on the magnetic body constituted by the yoke 31, the first additional magnetic body 32A, and the second additional magnetic body 32B. A part of the first additional magnetic body 32A is located off the yoke 31 in the Z direction. A part of the second additional magnetic body 32B is located off the yoke 31 in the −Z direction. When the external magnetic field in the Z direction is applied to the magnetic body, a path for a magnetic flux to pass through is formed in a direction from the second additional magnetic body 32B to the first additional magnetic body 32A via the yoke 31, and the magnetic body is magnetized in the direction. The first additional magnetic body 32A is connected to the end of the yoke 31 in the X direction. The second additional magnetic body 32B is connected to the end of the yoke 31 in the −X direction. The yoke 31 is thus magnetized in the X direction.

Now, in some cases, a noise magnetic field in the direction parallel to the X direction is applied to the magnetic sensor 1, aside from the magnetic field to be detected. The magnetization direction of the free layer 24 in each of the plurality of MR elements 20 changes from the direction when the presence of only the input magnetic field component is assumed, depending on the magnetization direction of the yoke 31. If, for example, the direction of the noise magnetic field changes from the X direction to the −X direction and the magnetization direction of the yoke 31 changes accordingly, the amount of change in the magnetization direction of the free layer 24 also changes. This consequently changes the characteristics obtained from the output of the magnetic sensor 1 when the magnetic field to be detected is continuously changed, like linearity and hysteresis.

By contrast, in the present example embodiment, as described above, the magnetic field to be detected is always applied to the magnetic field 1 when the magnetic sensor 1 is in use. In the present example embodiment, the magnetic field to be detected thus keeps the yoke 31 magnetized in the X direction. According to the present example embodiment, a change in the characteristics of the magnetic sensor 1 due to a change in the magnetization direction of the yoke 31 can thereby be prevented.

Next, the magnetic field to be detected by the magnetic sensor 1 will be described. The magnetic field to be detected may be a magnetic field generated by a magnetic field generator such as a magnet. In such a case, the magnetic field generator may be a component of the magnetic sensor 1.

FIG. 9 is a front view showing the magnetic sensor 1 and a magnetic field generator 5. The magnetic field generator 5 is configured to generate a magnetic field to be applied to the plurality of yokes 31. The magnetic field generator 5 may be a magnet configured to generate a magnetic field including a component in the direction parallel to the Z direction. In the example shown in FIG. 9, the magnetic field generator 5 is configured to have a magnetization in the Z direction and generate a magnetic field including a component in the Z direction. The example shown in FIG. 9 is not restrictive, and the magnetic field generator 5 may be configured to have a magnetization in a plurality of directions other than the Z direction in addition to or instead of the magnetization in the Z direction. In the example shown in FIG. 9, the magnetic sensor 1 is located forward of the magnetic field generator 5 in the −Z direction. In such a case, the magnetic field to be detected includes a component in the Z direction, but does not include a component in the −Z direction.

When the relative position of the magnetic sensor 1 and the magnetic field generator 5 changes, the strength of the magnetic field applied to the plurality of yokes 31, i.e., the strength of the input magnetic field component changes. As described above, the detection signal of the magnetic sensor 1 has a correspondence with the strength of the input magnetic field component. The detection signal of the magnetic sensor 1 thus has a correspondence with the relative position of the magnetic sensor 1 and the magnetic field generator 5. The relative position of the magnetic sensor 1 and the magnetic field generator 5 changes in the direction parallel to the Z direction, for example.

Next, the position detection device 50 according to the present example embodiment will be briefly described with reference to FIG. 9. The position detection device 50 according to the present example embodiment includes the magnetic sensor 1 according to the present example embodiment and the magnetic field generator 5. The magnetic sensor 1 and the magnetic field generator 5 are configured so that the relative position of the magnetic sensor 1 and the magnetic field generator 5 changes with the position of an object whose position is variable. As described above, the detection signal of the magnetic sensor 1 has a correspondence with the relative position of the magnetic sensor 1 and the magnetic field generator 5. The position detection device 50 detects the position of the object by measuring the detection signal of the magnetic sensor 1.

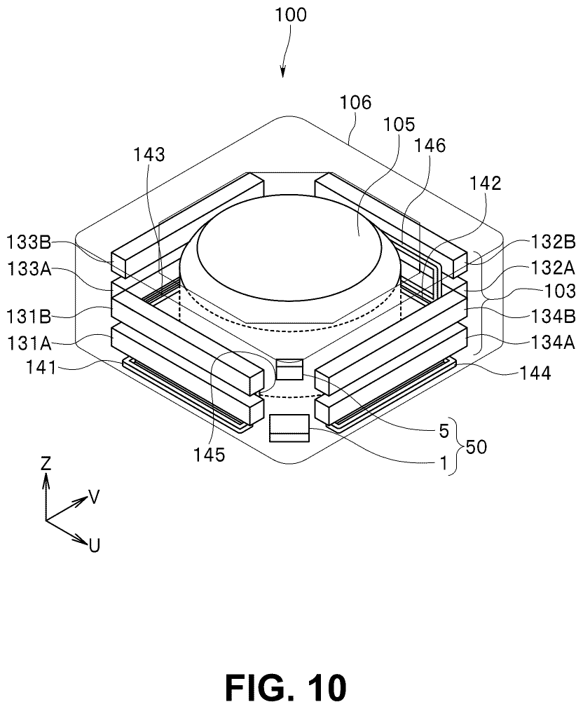

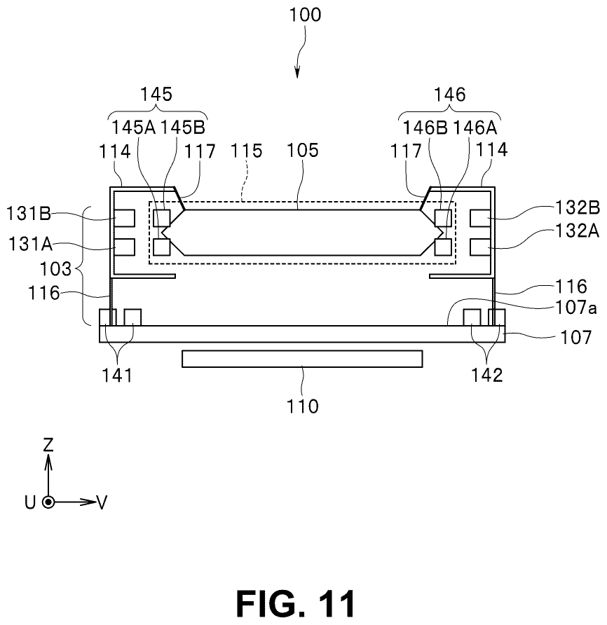

Next, a lens module 100 according to the present example embodiment will be described with reference to FIGS. 10 and 11. FIG. 10 is a perspective view of the lens module 100. FIG. 11 is an explanatory diagram schematically showing an interior of the lens module 100. For ease of understanding, in FIG. 11 the parts of the lens module 100 are drawn on a different scale and in a different layout than those in FIG. 10. The lens module 100 according to the present example embodiment constitutes, for example, a portion of a camera for a smartphone having an optical image stabilization mechanism and an autofocus mechanism, and is used in combination with an image sensor 110 that uses CMOS or other similar techniques.

The lens module 100 according to the present example embodiment includes a position detection device 50 according to the present example embodiment, and a driving device 103, a lens 105, a housing 106 and a substrate 107. The position detection device 50 according to the present example embodiment is used to detect the position of the lens 105 during automatic focusing. The driving device 103 is to move the lens 105. The housing 106 is to protect the position detection device 50 and the driving device 103. The substrate 107 has a top surface 107a. FIG. 10 omits the illustration of the substrate 107, and FIG. 11 omits the illustration of the housing 106.

Now, we define U and V directions as shown in FIGS. 10 and 11. The U direction is the direction rotated by 45° from the X direction toward the −Y direction. The V direction is the direction rotated by 45° from the X direction toward the Y direction. The U direction and the V direction are both orthogonal to the Z direction. In terms of the lens module 100, a direction perpendicular to the top surface 107a of the substrate 107 (upward direction in FIG. 11) will be referred to as the Z direction. The U and V directions are both parallel to the top surface 107a of the substrate 107. The opposite directions to the U and V directions will be referred to as -U and -V directions, respectively.

The lens 105 is disposed above the top surface 107a of the substrate 107 in such an orientation that the direction of its optical axis is parallel to the Z direction. The substrate 107 has an opening (not illustrated) for passing light that has passed through the lens 105. As shown in FIG. 11, the lens module 100 is in alignment with the image sensor 110 so that light that has passed through the lens 105 and the not-shown opening will enter the image sensor 110.

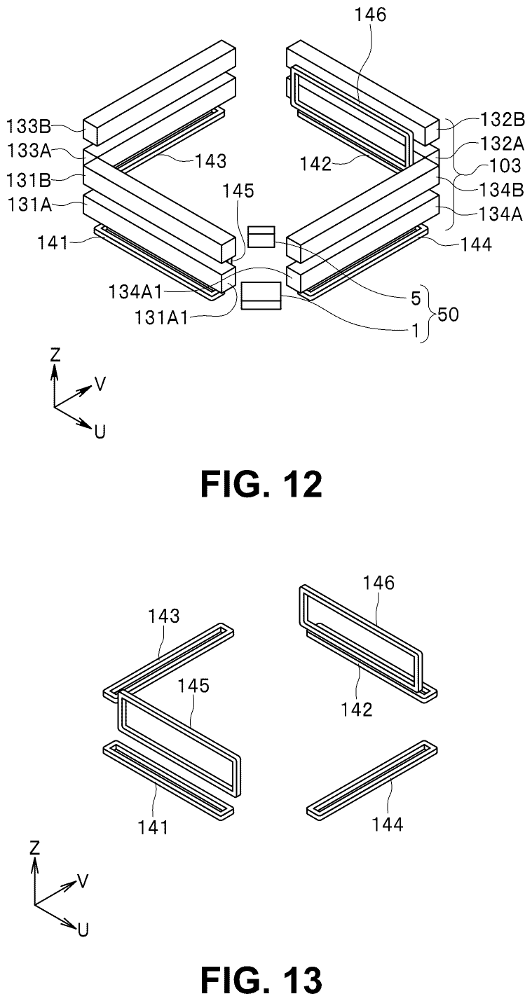

The position detection device 50 and the driving device 103 according to the present example embodiment will now be described in detail with reference to FIG. 11 to FIG. 13. FIG. 12 is a perspective view of the position detection device 50 and the driving device 103. FIG. 13 is a perspective view of a plurality of coils of the driving device 103.

The position detection device 50 includes a first holding member 114, a second holding member 115, a plurality of first wires 116, and a plurality of second wires 117. The second holding member 115 is to hold the lens 105. Although not shown, the second holding member 115 is shaped like, for example, a hollow cylinder so that the lens 105 is insertable in the hollow.

The second holding member 115 is provided such that its position is variable in one direction, specifically, in the direction of the optical axis of the lens 105, i.e., a direction parallel to the Z direction, relative to the first holding member 114. In the present example embodiment, the first holding member 114 is shaped like a box so that the lens 105 and the second holding member 115 can be accommodated therein. The plurality of second wires 117 connect the first and second holding members 114 and 115, and support the second holding member 115 such that the second holding member 115 is movable in a direction parallel to the Z direction relative to the first holding member 114.

The first holding member 114 is provided above the top surface 107a of the substrate 107 such that its position is variable relative to the substrate 107 in a direction parallel to the U direction and in a direction parallel to the V direction. The plurality of first wires 116 connect the substrate 107 and the first holding member 114, and support the first holding member 114 such that the first holding member 114 is movable relative to the substrate 107 in a direction parallel to the U direction and in a direction parallel to the V direction. When the position of the first holding member 114 relative to the substrate 107 varies, the position of the second holding member 115 relative to the substrate 107 also varies.

The driving device 103 includes magnets 131A, 131B, 132A, 132B, 133A, 133B, 134A, and 134B, and coils 141, 142, 143, 144, 145, and 146. The magnet 131A is located forward of the lens 105 in the −V direction. The magnet 132A is located forward of the lens 105 in the V direction. The magnet 133A is located forward of the lens 105 in the −U direction. The magnet 134A is located forward of the lens 105 in the U direction. The magnets 131B, 132B, 133B, and 134B are located above the magnets 131A, 132A, 133A, and 134A, respectively. The magnets 131A, 131B, 132A, 132B, 133A, 133B, 134A, and 134B are fixed to the first holding member 114.

As shown in FIG. 12, the magnets 131A, 131B, 132A, and 132B are each in the shape of a rectangular solid that is long in the U direction. The magnets 133A, 133B, 134A, and 134B are each in the shape of a rectangular solid that is long in the V direction. The magnets 131A and 132B are magnetized in the V direction. The magnets 131B and 132A are magnetized in the −V direction. The magnets 133A and 134B are magnetized in the U direction. The magnets 133B and 134A are magnetized in the −U direction.

The coil 141 is located between the magnet 131A and the substrate 107. The coil 142 is located between the magnet 132A and the substrate 107. The coil 143 is located between the magnet 133A and the substrate 107. The coil 144 is located between the magnet 134A and the substrate 107. The coil 145 is located between the lens 105 and the magnets 131A and 131B. The coil 146 is located between the lens 105 and the magnets 132A and 132B. The coils 141, 142, 143, and 144 are fixed to the substrate 107. The coils 145 and 146 are fixed to the second holding member 115.

The coil 141 is subjected mainly to a magnetic field generated by the magnet 131A. The coil 142 is subjected mainly to a magnetic field generated by the magnet 132A. The coil 143 is subjected mainly to a magnetic field generated by the magnet 133A. The coil 144 is subjected mainly to a magnetic field generated by the magnet 134A.

As shown in FIG. 11, the coil 145 includes a first conductor portion 145A extending along the magnet 131A in the U direction, a second conductor portion 145B extending along the magnet 131B in the U direction, and two third conductor portions connecting the first and second conductor portions 145A and 145B. As shown in FIG. 11, the coil 146 includes a first conductor portion 146A extending along the magnet 132A in the U direction, a second conductor portion 146B extending along the magnet 132B in the U direction, and two third conductor portions connecting the first and second conductor portions 146A and 146B.

The first conductor portion 145A of the coil 145 is subjected mainly to a component in the V direction of the magnetic field generated by the magnet 131A. The second conductor portion 145B of the coil 145 is subjected mainly to a component in the −V direction of a magnetic field generated by the magnet 131B. The first conductor portion 146A of the coil 146 is subjected mainly to a component in the −V direction of the magnetic field generated by the magnet 132A. The second conductor portion 146B of the coil 146 is subjected mainly to a component in the V direction of a magnetic field generated by the magnet 132B.

As described above, the position detection device 50 includes the magnetic sensor 1 and the magnetic field generator 5. The magnetic field generator 5 may be a magnet having a rectangular solid shape. As shown in FIG. 12, the magnet 131A has an end face 131A1 located at the end of the magnet 131A in the U direction. The magnet 134A has an end face 134A1 located at the end of the magnet 134A in the −V direction. The magnetic field generator 5 is fixed to the second holding member 115 in a space near the end face 131A1 of the magnet 131A and the end face 134A1 of the magnet 134A, for example.

The magnetic sensor 1 is fixed to the substrate 107 near the end face 131A1 of the magnet 131A and the end face 134A1 of the magnet 134A, for example. The distance between the magnet 131A and the magnetic sensor 1 is equal to the distance between the magnet 134A and the magnetic sensor 1. The magnetic field generator 5 is located above the magnetic sensor 1.

The driving device 103 further includes a not-shown first magnetic sensor fixed to the substrate 107 on the inner side of one of the coils 141 and 142, and a not-shown second magnetic sensor fixed to the substrate 107 on the inner side of the other of the coils 143 and 144. Assume here that the first and second magnetic sensors are disposed on the inner sides of the coils 141 and 144, respectively. As will be described later, the first and second magnetic sensors are used to vary the position of the lens 105 to reduce the effect of hand-induced camera shake.

The first magnetic sensor detects the magnetic field generated by the magnet 131A and generates a signal corresponding to the position of the magnet 131A. The second magnetic sensor detects the magnetic field generated by the magnet 134A and generates a signal corresponding to the position of the magnet 134A. For example, the first and second magnetic sensors are constructed of elements for detecting magnetic fields, such as Hall elements.

Reference is now made to FIGS. 11 to 13 to describe the operation of the driving device 103. Optical image stabilization and autofocus mechanisms will be bridfly described first. The driving device 103 constitutes part of the optical image stabilization and autofocus mechanisms. A control unit (not illustrated) external to the lens module 100 controls the driving device 103, the optical image stabilization mechanism, and the autofocus mechanism.

The optical image stabilization mechanism is configured to detect hand-induced camera shake using, for example, a gyrosensor external to the lens module 100. Upon detection of hand-induced camera shake by the optical image stabilization mechanism, the not-shown control unit controls the driving device 103 so as to vary the position of the lens 105 relative to the substrate 107 depending on the mode of the camera shake. This stabilizes the absolute position of the lens 105 to reduce the effect of the camera shake. The position of the lens 105 relative to the substrate 107 is varied in a direction parallel to the U direction or in a direction parallel to the V direction, depending on the mode of the camera shake.

The autofocus mechanism is configured to detect a state in which focus is achieved on the subject, using, for example, an image sensor 110 or an autofocus sensor. Using the driving device 103, the not-shown control unit varies the position of the lens 105 relative to the substrate 107 in a direction parallel to the Z direction so as to achieve focus on the subject. This enables automatic focusing on the subject.

Next, a description will be given of the operation of the driving device 103 related to the optical image stabilization mechanism. When currents are passed through the coils 141 and 142 by the not-shown control unit, the first holding member 114 with the magnets 131A and 132A fixed thereto moves in a direction parallel to the V direction due to interaction between the magnetic fields generated by the magnets 131A and 132A and the magnetic fields generated by the coils 141 and 142. As a result, the lens 105 also moves in the direction parallel to the V direction. On the other hand, when currents are passed through the coils 143 and 144 by the not-shown control unit, the first holding member 114 with the magnets 133A and 134A fixed thereto moves in a direction parallel to the U direction due to interaction between the magnetic fields generated by the magnets 133A and 134A and the magnetic fields generated by the coils 143 and 144. As a result, the lens 105 also moves in the direction parallel to the U direction. The not-shown control unit detects the position of the lens 105 by measuring signals corresponding to the positions of the magnets 131A and 134A, which are generated by the not-shown first magnetic sensor and the not-shown second magnetic sensor.

Next, the operation of the driving device 103 related to the autofocus mechanism will be described. To move the position of the lens 105 relative to the substrate 107 in the Z direction, the not-shown control unit passes a current through the coil 145 such that the current flows through the first conductor portion 145A in the U direction and flows through the second conductor portion 145B in the −U direction, and passes a current through the coil 146 such that the current flows through the first conductor portion 146A in the −U direction and flows through the second conductor portion 146B in the U direction. These currents and the magnetic fields generated by the magnets 131A, 131B, 132A, and 132B cause a Lorentz force in the Z direction to be exerted on the first and second conductor portions 145A and 145B of the coil 145 and the first and second conductor portions 146A and 146B of the coil 146. This causes the second holding member 115 with the coils 145 and 146 fixed thereto to move in the Z direction. As a result, the lens 105 also moves in the Z direction.

To move the position of the lens 105 relative to the substrate 107 in the −Z direction, the not-shown control unit passes currents through the coils 145 and 146 in directions opposite to those in the case of moving the position of the lens 105 relative to the substrate 107 in the Z direction.

Next, operation of the position detection device 50 included in the lens module 100 will be described. The position detection device 50 is used to detect the position of an object whose position is variable. For the lens module 100, the object is the lens 105 whose position is variable in a linear direction.

If the position of the lens 105 relative to the substrate 107 changes, the position of the second holding member 115 relative to the substrate 107 and the first holding member 114 also changes. As described above, the second holding member 115 holds the magnetic field generator 5. When the relative position of the lens 105 changes as described above, the position of the magnetic field generator 5 relative to the magnetic sensor 1 disposed on the substrate 107 therefore changes. As described above, the detection signal of the magnetic sensor 1 has a correspondence with the relative position of the magnetic sensor 1 and the magnetic field generator 5. The position detection device 50 detects the position of the lens 105 by measuring the detection signal of the magnetic sensor 1.

### Second Example Embodiment

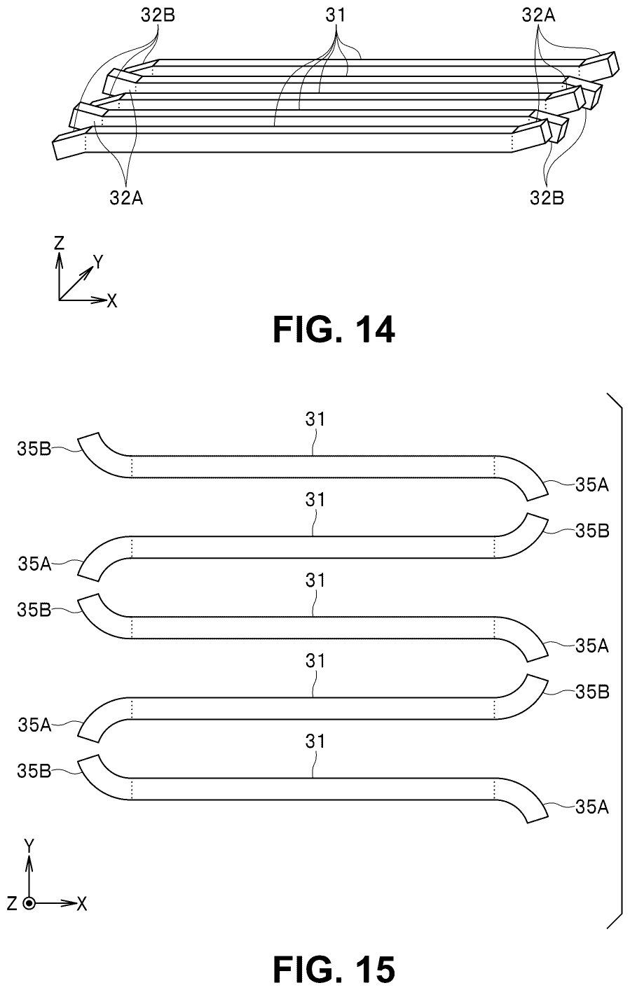

Next, a second example embodiment of the technology will be described with reference to FIG. 14. FIG. 14 is a perspective view showing a plurality of yokes and a plurality of additional magnetic bodies of the present example embodiment.

Differences of a soft magnetic structure 30 of the present example embodiment from that of the first example embodiment will be described below. In the present example embodiment, a plurality of first additional magnetic bodies 32A and a plurality of second additional magnetic bodies 32B are each connected to the end of a corresponding yoke 31 in the X direction or the −X direction. Some of the plurality of first additional magnetic bodies 32A connected to the ends of the respective corresponding yokes 31 in the X direction and some of the plurality of second additional magnetic bodies 32B connected to the ends of the respective corresponding yokes 31 in the X direction are arranged so that the first additional magnetic bodies 32A and the second additional magnetic bodies 32B alternate in the direction parallel to the Y direction. Similarly, some of the plurality of first additional magnetic bodies 32A connected to the ends of the respective corresponding yokes 31 in the −X direction and some of the plurality of second additional magnetic bodies 32B connected to the ends of the respective corresponding yokes 31 in the −X direction are arranged so that the first additional magnetic bodies 32A and the second additional magnetic bodies 32B alternate in the direction parallel to the Y direction. In other words, the plurality of first additional magnetic bodies 32A and the plurality of second additional magnetic bodies 32B are located so that the first additional magnetic bodies 32A and the second additional magnetic bodies 32B are adjacent to one another in the direction parallel to the Y direction.

A structure including a yoke 31, a first additional magnetic body 32A connected to the end of the yoke 31 in the X direction, and a second additional magnetic body 32B connected to the end of the yoke 31 in the −X direction will be referred to as a first magnetic body. A structure including a yoke 31, a first additional magnetic body 32A connected to the end of the yoke 31 in the −X direction, and a second additional magnetic body 32B connected to the end of the yoke 31 in the X direction will be referred to as a second magnetic body. A plurality of first magnetic bodies and a plurality of second magnetic bodies are arranged so that the first magnetic bodies and the second magnetic bodies alternate in the direction parallel to the Y direction.

In the present example embodiment, the yokes 31 of the first magnetic bodies are magnetized in the X direction by an external magnetic field in the Z direction, like the yokes 31 of the first example embodiment. The yokes 31 of the second magnetic bodies are magnetized in the −X direction, opposite to the yokes 31 of the first magnetic bodies. In the present example embodiment, the plurality of yokes 31 are therefore arranged so that the yokes 31 magnetized in the X direction and the yokes 31 magnetized in the −X direction alternate in the direction parallel to the Y direction. In other words, in the present example embodiment, a yoke 31 magnetized in the X direction and a yoke 31 magnetized in the −X direction are adjacent to each other in the direction parallel to the Y direction. The two yokes 31 are magnetically coupled with each other. According to the present example embodiment, the magnetization of the yokes 31 can thereby be stabilized. As a result, according to the present example embodiment, a change in the characteristics of the magnetic sensor 1 due to a change in the magnetization directions of the yokes 31 can be prevented.

The configuration, operation, and effects of the present example embodiment are otherwise the same as those of the first example embodiment.

### Third Example Embodiment

Next, a third example embodiment of the technology will be described with reference to FIG. 15. FIG. 15 is a plan view showing a plurality of yokes and a plurality of additional magnetic bodies of the present example embodiment.

Differences of a soft magnetic structure 30 of the present example embodiment from that of the first example embodiment will be described below. In the present example embodiment, the soft magnetic structure 30 includes a plurality of first additional magnetic bodies 35A and a plurality of second additional magnetic bodies 35B instead of the plurality of first additional magnetic bodies 32A and the plurality of second additional magnetic bodies 32B of the first example embodiment. As shown in FIG. 15, each of the plurality of first additional magnetic bodies 35A and each of the plurality of second additional magnetic bodies 35B are arranged next to a corresponding yoke 31 in the direction parallel to the X direction.

In the present example embodiment, the plurality of first additional magnetic bodies 35A and the plurality of second additional magnetic bodies 35B are each connected to the end of a corresponding yoke 31 in the X direction or the −X direction. A first additional magnetic body 35A and a second additional magnetic body 35B are connected to a yoke 31. In FIG. 15, the border between the yoke 31 and the first additional magnetic body 35A and the border between the yoke 31 and the second additional magnetic body 35B are both shown in dotted lines.

Some of the plurality of first additional magnetic bodies 35A connected to the ends of the respective corresponding yokes 31 in the X direction and some of the plurality of second additional magnetic bodies 35B connected to the ends of the respective corresponding yokes 31 in the X direction are arranged so that the first additional magnetic bodies 35A and the second additional magnetic bodies 35B alternate in the direction parallel to the Y direction. Similarly, some of the plurality of first additional magnetic bodies 35A connected to the ends of the respective corresponding yokes 31 in the −X direction and some of the plurality of second additional magnetic bodies 35B connected to the ends of the respective corresponding yokes 31 in the −X direction are arranged so that the first additional magnetic bodies 35A and the second additional magnetic bodies 35B alternate in the direction parallel to the Y direction. In other words, the plurality of first additional magnetic bodies 35A and the plurality of second additional magnetic bodies 35B are located so that the first additional magnetic bodies 35A and the second additional magnetic bodies 35B are adjacent to one another in the direction parallel to the Y direction.

As shown in FIG. 15, each of the plurality of first additional magnetic bodies 35A and each of the plurality of second additional magnetic bodies 35B may be located off the corresponding yoke 31 in the direction parallel to the Y direction. In particular, in the present example embodiment, each of the plurality of first additional magnetic bodies 35A extends from the end of the corresponding yoke 31 to bend in the −Y direction so that a part of the first additional magnetic body 35 is located off the yoke 31 in the −Y direction. Each of the second additional magnetic bodies 35B extends from the end of the corresponding yoke 31 to bend in the Y direction so that a part of the second additional magnetic body 35B is located off the yoke 31 in the Y direction.

A structure including a yoke 31, a first additional magnetic body 35A connected to the end of the yoke 31 in the X direction, and a second additional magnetic body 35B connected to the end of the yoke 31 in the −X direction will be referred to as a first magnetic body. A structure including a yoke 31, a first additional magnetic body 35A connected to the end of the yoke 31 in the −X direction, and a second additional magnetic body 35B connected to the end of the yoke 31 in the X direction will be referred to as a second magnetic body. A plurality of first magnetic bodies and a plurality of second magnetic bodies are arranged so that the first magnetic bodies and the second magnetic bodies alternate in the direction parallel to the Y direction.

In the present example embodiment, an external magnetic field in a direction parallel to the Y direction is always applied to the magnetic sensor 1 in addition to the magnetic field to be detected. A case where an external magnetic field in the Y direction is applied to the magnetic sensor 1 will now be described as an example. In such a case, the external magnetic field in the Y direction is applied to the plurality of yokes 31, the plurality of first additional magnetic bodies 35A, and the plurality of second additional magnetic bodies 35B.

A part of each first additional magnetic body 35A is located off the yoke 31 in the −Y direction. A part of each second additional magnetic body 35B is located off the yoke 31 in the Y direction. When the external magnetic field in the Y direction is applied to the first magnetic bodies and the second magnetic bodies, in each of the first and second magnetic bodies, a path for a magnetic flux to pass through is formed in a direction from the first additional magnetic body 35A to the second additional magnetic body 35B via the yoke 31, and the first magnetic bodies and the second magnetic bodies are both magnetized in the direction.

In the first magnetic bodies, the first additional magnetic bodies 35A are connected to the ends of the yokes 31 in the X direction, and the second additional magnetic bodies 35B are connected to the ends of the yokes 31 in the −X direction. The yokes 31 of the first magnetic bodies are thus magnetized in the −X direction. In the second magnetic bodies, the first additional magnetic bodies 35A are connected to the ends of the yokes 31 in the −X direction, and the second additional magnetic bodies 35B are connected to the ends of the yokes 31 in the X direction. The yokes 31 of the second magnetic bodies are thus magnetized in the X direction.

In the present example embodiment, like the second example embodiment, the plurality of yokes 31 are arranged so that the yokes 31 magnetized in the X direction and the yokes 31 magnetized in the −X direction alternate in the direction parallel to the Y direction. According to the present example embodiment, the magnetization of the yokes 31 can be stabilized for the same reason as described in the second example embodiment. As a result, according to the present example embodiment, a change in the characteristics of the magnetic sensor 1 due to a change in the magnetization directions of the yokes 31 can be prevented.

Like the plurality of first additional magnetic bodies 32A and the plurality of second additional magnetic bodies 32B of the first example embodiment, each of the plurality of first additional magnetic bodies 35A may be connected to the end of the corresponding yoke 31 in the X direction, and each of the plurality of second additional magnetic bodies 35B may be connected to the end of the corresponding yoke 31 in the −X direction.

The configuration, operation, and effects of the present example embodiment are otherwise the same as those of the first or second example embodiment.

### Fourth Example Embodiment

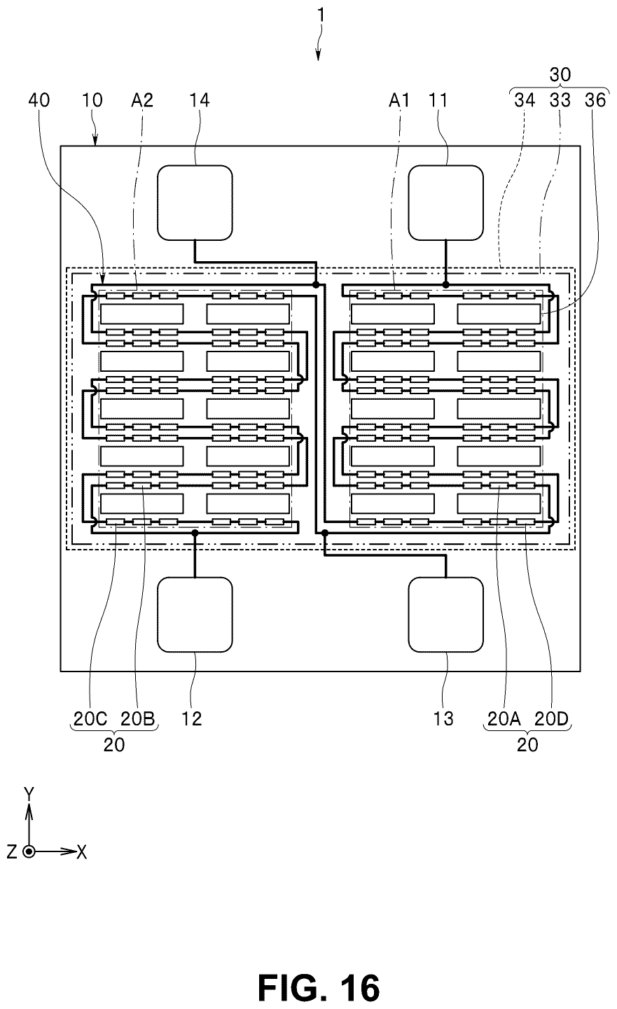

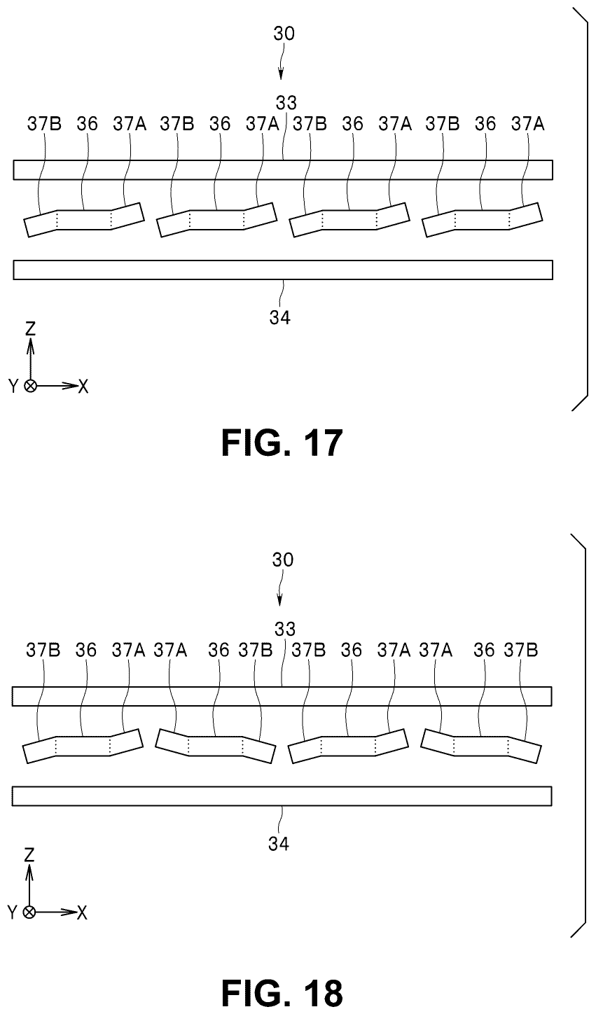

Next, a fourth example embodiment of the technology will be described with reference to FIGS. 16 and 17. FIG. 16 is a plan view showing a magnetic sensor according to the present example embodiment. FIG. 17 is a side view showing a soft magnetic structure of the present example embodiment, viewed in the −Y direction in FIG. 16.

Differences of a soft magnetic structure 30 of the present example embodiment from that of the first example embodiment will be described below. In the present example embodiment, the soft magnetic structure 30 includes a plurality of yokes 36 instead of the plurality of yokes 31 of the first example embodiment. Each of the plurality of yokes 36 has a rectangular solid shape extending in the direction parallel to the X direction. The plurality of yokes 36 are arranged in groups of two or more in the direction parallel to the X direction and the direction parallel to the Y direction in each of the areas A1 and A2. In particular, in the present example embodiment, the plurality of yokes 36 are arranged in twos in the direction parallel to the X direction and in fives in the direction parallel to the Y direction in each of the areas A1 and A2.

The positional relationship between the plurality of MR elements 20 and the plurality of yokes 36 is the same as that between the plurality of MR elements 20 and the plurality of yokes 31 of the first example embodiment. The positional relationship between the two shields 33 and 34 and the plurality of yokes 36 is the same as that between the two shields 33 and 34 and the plurality of yokes 31 of the first example embodiment except for the relationship about the center positions of the yokes 31 in the direction parallel to the X direction.

In the present example embodiment, the soft magnetic structure 30 includes a plurality of first additional magnetic bodies 37A and a plurality of second additional magnetic bodies 37B instead of the plurality of first additional magnetic bodies 32A and the plurality of second additional magnetic bodies 32B of the first example embodiment. The positional relationship and connections among the plurality of yokes 36, the plurality of first additional magnetic bodies 37A, and the plurality of second additional magnetic bodies 37B are the same as those among the plurality of yokes 31, the plurality of first additional magnetic bodies 32A, and the plurality of second additional magnetic bodies 32B of the first example embodiment. Each of the plurality of first additional magnetic bodies 37A has the same shape as that of each of the plurality of first additional magnetic bodies 32A. Each of the plurality of second additional magnetic bodies 37B has the same shape as that of each of the plurality of second additional magnetic bodies 32B. In FIG. 16, the plurality of first additional magnetic bodies 37A and the plurality of second additional magnetic bodies 37B are omitted.

As shown in FIG. 17, in the present example embodiment, the first additional magnetic bodies 37A and the second additional magnetic bodies 37B are adjacent to one another in the direction parallel to the X direction.

The configuration, operation, and effects of the present example embodiment are otherwise the same as those of the first example embodiment.

### First to Third Modification Examples

Next, first to third modification examples of the soft magnetic structure 30 of the present example embodiment will be described. The first modification example will initially be described with reference to FIG. 18. FIG. 18 is a side view showing the first modification example of the soft magnetic structure 30.

As shown in FIG. 18, in the first modification example, the plurality of first additional magnetic bodies 37A and the plurality of second additional magnetic bodies 37B are connected to the respective corresponding yokes 36 so that two first additional magnetic bodies 37A are adjacent to each other and two second additional magnetic bodies 37B are adjacent to each other in the direction parallel to the X direction.

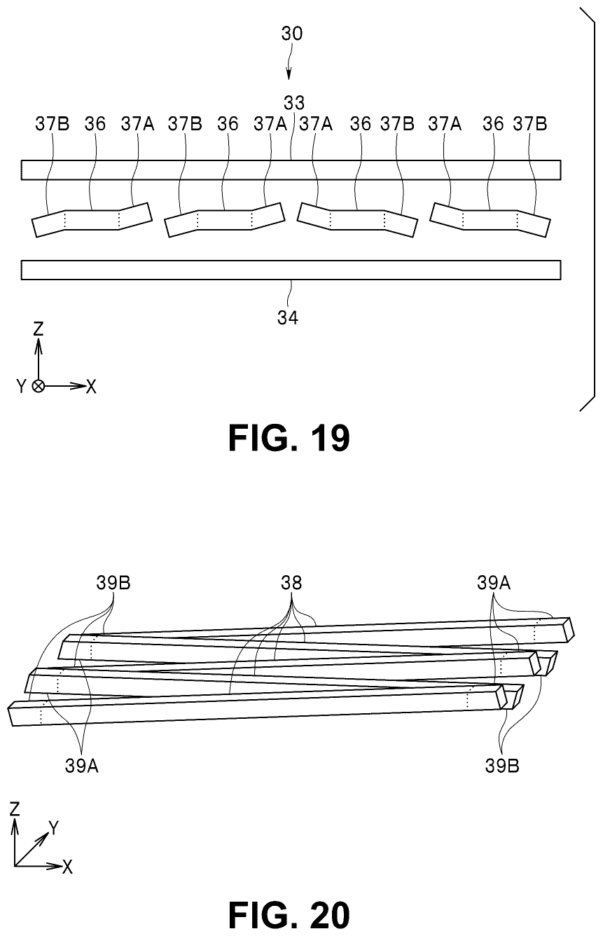

Next, the second modification example will be described with reference to FIG. 19. FIG. 19 is a side view showing the second modification example of the soft magnetic structure 30.

A structure including a yoke 36 and first and second additional magnetic bodies 37A and 37B connected to the yoke 36 will be referred to a specific magnetic body. The soft magnetic structure 30 includes a plurality of specific magnetic bodies. The plurality of specific magnetic bodies are arranged in groups of two or more in the direction parallel to the X direction and the direction parallel to the Y direction.

The soft magnetic structure 30 includes a plurality of magnetic body groups each including some of the plurality of specific magnetic bodies. Now, focus attention on two magnetic body groups adjacent in the direction parallel to the X direction. In the second modification example, the connections among the plurality of yokes 36, the plurality of first additional magnetic bodies 37A, and the plurality of second additional magnetic bodies 37B in one of the two magnetic body groups (hereinafter, referred to as a first group) and the connections among the plurality of yokes 36, the plurality of first additional magnetic bodies 37A, and the plurality of second additional magnetic bodies 37B in the other of the two magnetic body groups (hereinafter, referred to as a second group) are opposite to each other. More specifically, in the first group, each of the plurality of first additional magnetic bodies 37A is connected to the end of the corresponding yoke 36 in the X direction, and each of the plurality of second additional magnetic bodies 37B is connected to the end of the corresponding yoke 36 in the −X direction. In the second group, each of the plurality of first additional magnetic bodies 37A is connected to the end of the corresponding yoke 36 in the −X direction, and each of the plurality of second additional magnetic bodies 37B is connected to the end of the corresponding yoke 36 in the X direction.

Next, the third modification example will be briefly described. In the third modification example, two or more first groups according to the second modification example are arranged in a row and two or more second groups according to the second modification example are arranged in a row in the direction parallel to the X direction. Moreover, the two or more first groups and the two or more second groups are arranged so that the first groups and the second groups alternate in the direction parallel to the X direction.

### Fifth Example Embodiment

Next, a fifth example embodiment of the technology will be described with reference to FIG. 20. FIG. 20 is a perspective view showing a plurality of yokes and a plurality of additional magnetic bodies of the present example embodiment.

Differences of a soft magnetic structure 30 of the present example embodiment from that of the first example embodiment will be described below. In the present example embodiment, the soft magnetic structure 30 includes a plurality of yokes 38 instead of the plurality of yokes 31 of the first example embodiment. Each of the plurality of yokes 38 has a rectangular solid shape extending in a direction parallel to a direction that intersects both the X and Z directions and is orthogonal to the Y direction.

Each of the plurality of yokes 38 has a first end located at the end in the X direction, and a second end located at the end in the −X direction. In particular, in the present example embodiment, the plurality of yokes 38 include a plurality of first specific yokes and a plurality of second specific yokes. Each of the plurality of first specific yokes tilts with respect to the direction parallel to the X direction so that the vicinity of the first end is located off the vicinity of the second end in the Z direction. Each of the plurality of second specific yokes tilts with respect to the direction parallel to the X direction so that the vicinity of the first end is located off the vicinity of the second end in the −Z direction. The plurality of first specific yokes and the plurality of second specific yokes are arranged so that the first specific yokes and the second specific yokes alternate in the direction parallel to the Y direction.

The positional relationship between the plurality of MR elements 20 and the plurality of yokes 38 is the same as that between the plurality of MR elements 20 and the plurality of yokes 31 of the first example embodiment. The positional relationship between the two shields 33 and 34 and the plurality of yokes 38 is the same as that between the two shields 33 and 34 and the plurality of yokes 31 of the first example embodiment.

In the present example embodiment, the soft magnetic structure 30 includes a plurality of first additional magnetic bodies 39A and a plurality of second additional magnetic bodies 39B instead of the plurality of first additional magnetic bodies 32A and the plurality of second additional magnetic bodies 32B of the first example embodiment. The positional relationship and connections among the plurality of yokes 38, the plurality of first additional magnetic bodies 39A, and the plurality of second additional magnetic bodies 39B are the same as those among the plurality of yokes 31, the plurality of first additional magnetic bodies 32A, and the plurality of second additional magnetic bodies 32B of the second example embodiment.

An entire structure including a yoke 38 and first and second additional magnetic bodies 39A and 39B connected to the yoke 38 may extend in the extending direction of the yoke 38. In other words, each of the plurality of first additional magnetic bodies 39A may extend in the extending direction of the corresponding yoke 38 so that a part of the first additional magnetic body 39A is located off the yoke 38 in the Z direction. Each of the plurality of second additional magnetic bodies 39B may extend in the extending direction of the corresponding yoke 38 so that a part of the second additional magnetic body 39B is located off the yoke 38 in the −Z direction.

The plurality of yokes 38 may include only a plurality of first specific yokes, or only a plurality of second specific yokes.

The configuration, operation, and effects of the present example embodiment are otherwise the same as those of the first or second example embodiment.

### Sixth Example Embodiment

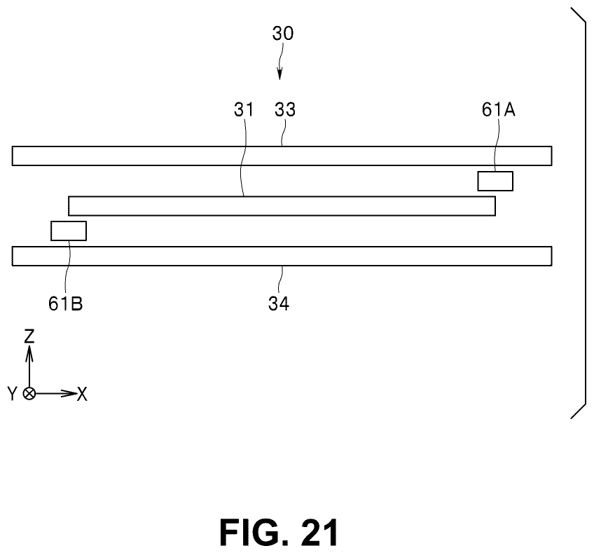

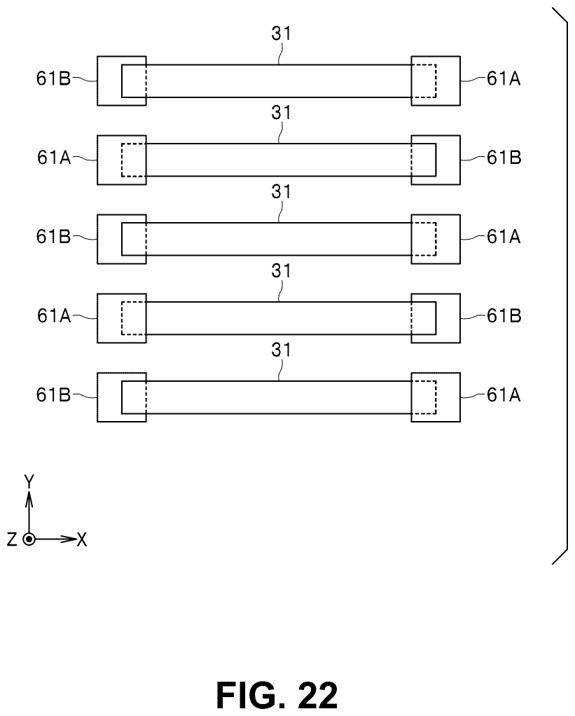

Next, a sixth example embodiment of the technology will be described with reference to FIGS. 21 and 22. FIG. 21 is a side view showing a soft magnetic structure of the present example embodiment. FIG. 22 is a plan view showing a plurality of yokes and a plurality of additional magnetic bodies of the present example embodiment.

Differences of a soft magnetic structure 30 of the present example embodiment from that of the first example embodiment will be described below. In the present example embodiment, the soft magnetic structure 30 includes a plurality of first additional magnetic bodies 61A and a plurality of second additional magnetic bodies 61B instead of the plurality of first additional magnetic bodies 32A and the plurality of second additional magnetic bodies 32B of the first example embodiment. The plurality of first additional magnetic bodies 61A and the plurality of second additional magnetic bodies 61B each have a rectangular solid shape, for example.

As shown in FIGS. 21 and 22, each of the plurality of first additional magnetic bodies 61A and each of the plurality of second additional magnetic bodies 61B are arranged next to a corresponding yoke 31 in the direction parallel to the X direction. In the present example embodiment, the plurality of first additional magnetic bodies 61A and the plurality of second additional magnetic bodies 61B are each located near the end of the corresponding yoke 31 in the X direction or the −X direction.

Some of the plurality of first additional magnetic bodies 61A located near the ends of the respective corresponding yokes 31 in the X direction and some of the plurality of second additional magnetic bodies 61B located near the ends of the respective corresponding yokes 31 in the X direction are arranged so that the first additional magnetic bodies 61A and the second additional magnetic bodies 61B alternate in the direction parallel to the Y direction. Similarly, some of the plurality of first additional magnetic bodies 61A located near the ends of the respective corresponding yokes 31 in the −X direction and some of the plurality of second additional magnetic bodies 61B located near the ends of the respective corresponding yokes 31 in the −X direction are arranged so that the first additional magnetic bodies 61A and the second additional magnetic bodies 61B alternate in the direction parallel to the Y direction. In other words, when viewed in the Z direction, a first additional magnetic body 61A and a second additional magnetic body 61B are adjacent to each other in the direction parallel to the Y direction.

As shown in FIGS. 21 and 22, each of the plurality of first additional magnetic bodies 61A and each of the plurality of second additional magnetic bodies 61B are located off the corresponding yoke 31 in the direction parallel to the Z direction. In particular, in the present example embodiment, each of the plurality of first additional magnetic bodies 61A is located forward of the corresponding yoke 31 in the Z direction. Each of the second additional magnetic bodies 61B is located forward of the corresponding yoke 31 in the −Z direction. A first additional magnetic body 61A and a second additional magnetic body 61B are located so that at least a part of a yoke 31 is interposed between the first additional magnetic body 61A and the second additional magnetic body 61B.

In the example shown in FIGS. 21 and 22, the plurality of first additional magnetic bodies 61A and the plurality of second additional magnetic bodies 61B are each located at a predetermined distance from the corresponding yoke 31 in the direction parallel to the Z direction. In the example shown in FIGS. 21 and 22, the plurality of first additional magnetic bodies 61A and the plurality of second additional magnetic bodies 61B are each located so that a part of each of the additional magnetic bodies overlaps the corresponding yoke 31 when viewed in the Z direction.

The layout and shapes of the plurality of first additional magnetic bodies 61A and the plurality of second additional magnetic bodies 61B are not limited to the example shown in FIGS. 21 and 22. For example, the plurality of first additional magnetic bodies 61A and the plurality of second additional magnetic bodies 61B may be each located not to overlap the corresponding yoke 31 when viewed in the Z direction.

Suppose that a first additional magnetic body 61A is located near the end of a yoke 31 in the X direction and a second additional magnetic body 61B is located near the end of the yoke 31 in the −X direction. In such a case, the end of the yoke 31 in the X direction and the end of the first additional magnetic body 61A in the X direction may be located to match or almost match each other in the direction parallel to the X direction. The end of the yoke 31 in the −X direction and the end of the second additional magnetic body 61B in the −X direction may be located to match or almost match each other in the direction parallel to the X direction. Alternatively, the end of the yoke 31 in the −X direction and the end of the first additional magnetic body 61A in the X direction may be located to match or almost match each other in the direction parallel to the X direction. The end of the yoke 31 in the −X direction and the end of the second additional magnetic body 61B in the X direction may be located to match or almost match each other in the direction parallel to the X direction.

The plurality of first additional magnetic bodies 61A and the plurality of second additional magnetic bodies 61B each may be in contact with the corresponding yoke 31.

In the example shown in FIG. 21, the dimension of each of the plurality of first additional magnetic bodies 61A and the plurality of second additional magnetic bodies 61B in the direction parallel to the Z direction is the same or almost the same as that of each of the plurality of yokes 31 in the direction parallel to the Z direction. However, the dimension of each of the plurality of first additional magnetic bodies 61A and the plurality of second additional magnetic bodies 61B in the direction parallel to the Z direction may be greater than or smaller than that of each of the plurality of yokes 31 in the direction parallel to the Z direction.

In the example shown in FIG. 22, the dimension of each of the plurality of first additional magnetic bodies 61A and the plurality of second additional magnetic bodies 61B in the direction parallel to the Y direction is greater than that of each of the plurality of yokes 31 in the direction parallel to the Y direction. However, the dimension of each of the plurality of first additional magnetic bodies 61A and the plurality of second additional magnetic bodies 61B in the direction parallel to the Y direction may be the same as that of each of the plurality of yokes 31 in the direction parallel to the Y direction, or smaller than that of each of the plurality of yokes 31 in the direction parallel to the Y direction.

The plurality of first additional magnetic bodies 61A and the plurality of second additional magnetic bodies 61B may be formed of the same magnetic material as that of the plurality of yokes 31, or a magnetic material different from that of the plurality of yokes 31.

The number of the plurality of yokes 31 will be represented by N (N is an integer greater than or equal to 2). The sum of the number of first additional magnetic bodies 61A and the number of second additional magnetic bodies 61B is 2N.

In the present example embodiment, each of the two shields 33 and 34 covers the plurality of MR elements 20, the plurality of yokes 31, the plurality of first additional magnetic bodies 61A, and the plurality of second additional magnetic bodies 61B when viewed in the Z direction. The shield 33 is located forward of the plurality of MR elements 20, the plurality of yokes 31, the plurality of first additional magnetic bodies 61A, and the plurality of second additional magnetic bodies 61B in the Z direction. The shield 34 is located forward of the plurality of MR elements 20, the plurality of yokes 31, the plurality of first additional magnetic bodies 61A, and the plurality of second additional magnetic bodies 61B in the −Z direction.

The plurality of first additional magnetic bodies 61A and the plurality of second additional magnetic bodies 61B have the same function as that of the plurality of first additional magnetic bodies 32A and the plurality of second additional magnetic bodies 32B described in the first example embodiment. More specifically, the plurality of first additional magnetic bodies 61A and the plurality of second magnetic bodies 61B have a function of magnetizing each of the plurality of yokes 31 in the X direction or the −X direction when there is an external magnetic field in the Z direction.

Like the plurality of first additional magnetic bodies 32A and the plurality of second additional magnetic bodies 32B of the first example embodiment, the plurality of first additional magnetic bodies 61A each may be located near the end of the corresponding yoke 31 in the X direction, and the plurality of second additional magnetic bodies 61B each may be located near the end of the corresponding yoke 31 in the −X direction.

The configuration, operation, and effects of the present example embodiment are otherwise the same as those of the first or second example embodiment.

### Seventh Example Embodiment

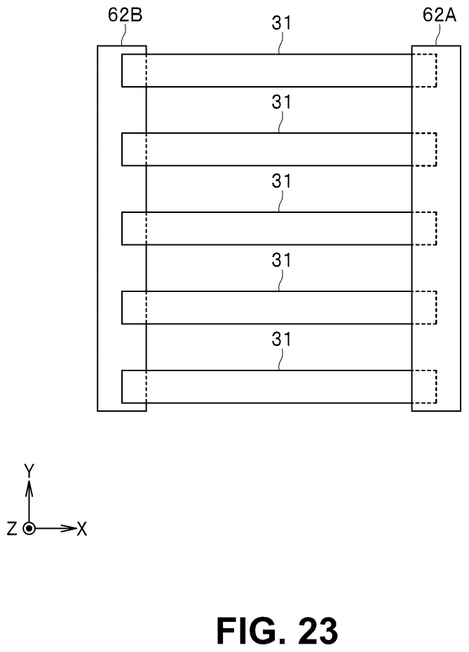

Next, a seventh example embodiment of the technology will be described with reference to FIG. 23. FIG. 23 is a plan view showing a plurality of yokes and a plurality of additional magnetic bodies of the present example embodiment.

Differences of a soft magnetic structure 30 of the present example embodiment from that of the sixth example embodiment will be described below. In the present example embodiment, the soft magnetic structure 30 includes a first additional magnetic body 62A and a second additional magnetic body 62B instead of the plurality of first additional magnetic bodies 61A and the plurality of second additional magnetic bodies 61B of the sixth example embodiment. Each of the first and second additional magnetic bodies 62A and 62B has a rectangular solid shape extending in the direction parallel to the Y direction. As shown in FIG. 23, the first additional magnetic body 62A and the second additional magnetic body 62B are arranged next to the plurality of yokes 31 in the direction parallel to the X direction.

The first additional magnetic body 62A is located near the end of each of the plurality of yokes 31 in the X direction. The first additional magnetic body 62A is located forward of the plurality of yokes 31 in the Z direction.

The second additional magnetic body 62B is located near the end of each of the plurality of yokes 31 in the −X direction. The second additional magnetic body 62B is located forward of the plurality of yokes 31 in the −Z direction.

In other respects, the positional relationship between the plurality of yokes 31 and the first and second additional magnetic bodies 62A and 62B is the same as that between the yokes 31 and the first and second additional magnetic bodies 61A and 61B of the sixth example embodiment.

In the example shown in FIG. 23, the first additional magnetic body 62A is located to overlap all the yokes 31. However, the first additional magnetic body 62A may be located to overlap at least one of the plurality of yokes 31. In such a case, the soft magnetic structure 30 may further include a third additional magnetic body adjacent to the first additional magnetic body 62A in the direction parallel to the Y direction. The third additional magnetic body is located near the end of at least another of the plurality of yokes 31 in the X direction. The third additional magnetic body may be located forward of the at least another yoke in the Z direction or the −Z direction.

Similarly, in the example shown in FIG. 23, the second additional magnetic body 62B is located to overlap all the yokes 31. However, the second additional magnetic body 62B may be located to overlap at least one of the plurality of yokes 31. In such a case, the soft magnetic structure 30 may further include a fourth additional magnetic body adjacent to the second additional magnetic body 62B in the direction parallel to the Y direction. The fourth additional magnetic body is located near the end of at least another of the plurality of yokes 31 in the −X direction. The fourth additional magnetic body may be located forward of the at least another yoke in the Z direction or the −Z direction.

The configuration, operation, and effects of the present example embodiment are otherwise the same as those of the sixth example embodiment.

### Eighth Example Embodiment

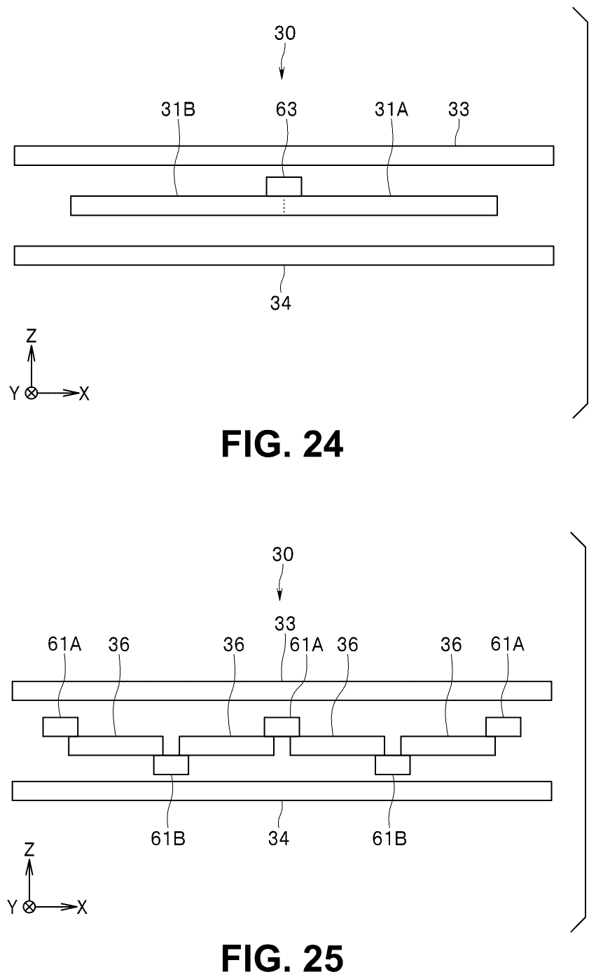

Next, an eighth example embodiment of the technology will be described with reference to FIG. 24. FIG. 24 is a side view showing a soft magnetic structure of the present example embodiment.

Differences of a soft magnetic structure 30 of the present example embodiment from that of the sixth example embodiment will be described below. In the present example embodiment, the soft magnetic structure 30 includes a plurality of first yokes 31A and a plurality of second yokes 31B instead of the plurality of yokes 31. The plurality of first yokes 31A are arranged in the direction parallel to the Y direction. The plurality of second yokes 31B are arranged in the direction parallel to the Y direction, and located forward of the plurality of first yokes 31A in the −X direction. In particular, in the present example embodiment, a first yoke 31A and a second yoke 31B adjacent in the direction parallel to the X direction are connected to each other. In FIG. 24, the border between the first yoke 31A and the second yoke 31B is shown in a dotted line.

In the present example embodiment, the soft magnetic structure 30 includes at least one additional magnetic body 63 instead of the plurality of first additional magnetic bodies 61A and the plurality of second additional magnetic body 61B of the sixth example embodiment. The at least one additional magnetic body 63 is arranged next to the plurality of first yokes 31A and the plurality of second yokes 31B in the direction parallel to the X direction. In the present example embodiment, the at least one additional magnetic body 63 is located near the borders between the first yokes 31A and the second yokes 31B.

The at least one additional magnetic body 63 is located off the plurality of first yokes 31A and the plurality of second yokes 31B in the direction parallel to the Z direction. In particular, in the present example embodiment, the at least one additional magnetic body 63 is located forward of the plurality of first yokes 31A and the plurality of second yokes 31B in the Z direction. The at least one additional magnetic body 63 may or may not be in contact with the plurality of first yokes 31A and the plurality of second yokes 31B.

Like the plurality of first additional magnetic bodies 61A and the plurality of second magnetic bodies 61B of the sixth example embodiment, the at least one additional magnetic body 63 may include a plurality of additional magnetic bodies 63. In such a case, each of the plurality of additional magnetic bodies 63 is located to overlap a corresponding first yoke 31A and a corresponding second yoke 31B when viewed in the Z direction. Each of the plurality of additional magnetic bodies 63 has the same shape as that of each of the plurality of first additional magnetic bodies 61A or the plurality of second additional magnetic bodies 61B.

Alternatively, like the first additional magnetic body 62A or the second additional magnetic body 62B of the seventh example embodiment, the at least one additional magnetic body 63 may include a single additional magnetic body 63. In such a case, the single additional magnetic body 63 is located to overlap the plurality of first yokes 31A and the plurality of second yokes 31B when viewed in the Z direction. The single additional magnetic body 63 has the same shape as that of the first additional magnetic body 62A or the second additional magnetic body 62B.

The sum of the number of first yokes 31A and the number of second yokes 31B is represented by N (N is an integer greater than or equal to 4). The number of at least one additional magnetic body 63 is less than 2N.

The positional relationship among the plurality of MR elements 20, the plurality of first yokes 31A, and the plurality of second yokes 31B is the same as that among the plurality of MR elements 20 and the plurality of yokes 31 of the first example embodiment except in the following: in the present example embodiment, the plurality of MR elements 20 are not arranged next to the at least one additional magnetic body 63 in the direction parallel to the Z direction.

In the present example embodiment, if the magnetic field to be detected by the magnetic sensor 1 includes a component in the −Z direction but not include a component in the Z direction, an external magnetic field in the −Z direction is applied to the plurality of first yokes 31A, the plurality of second yokes 31B, and the at least one additional magnetic body 63. In such a case, there are formed first paths for a magnetic flux to pass through in a direction from the at least one additional magnetic body 63 to the plurality of first yokes 31A and second paths for a magnetic flux to pass through in a direction from the at least one additional magnetic body 63 to the plurality of second yokes 31B. This magnetizes each of the plurality of first yokes 31A in the X direction and each of the plurality of second yokes 31B in the −X direction. According to the present example embodiment, each of the plurality of first yokes 31A and each of the plurality of second yokes 31B are magnetized in opposite directions, whereby the magnetization of each of the plurality of first yokes 31A and the magnetization of each of the plurality of second yokes 31B can be stabilized. As a result, according to the present example embodiment, a change in the characteristics of the magnetic sensor 1 due to a change in the magnetization direction of each of the plurality of first yokes 31A and the plurality of second yokes 31B can be prevented.

The configuration, operation, and effects of the present example embodiment are otherwise the same as those of the sixth or seventh example embodiment.

### Ninth Example Embodiment

Next, a ninth example embodiment of the technology will be described with reference to FIG. 25. FIG. 25 is a side view showing a soft magnetic structure according to the present example embodiment.

Differences of a soft magnetic structure 30 according to the present example embodiment from that of the sixth example embodiment will be described below. In the present example embodiment, the soft magnetic structure 30 includes the plurality of yokes 36 of the fourth example embodiment instead of the plurality of yokes 31 according to the sixth example embodiment.

In the present example embodiment, some of the plurality of first additional magnetic bodies 61A are located to overlap the end in the X direction of one of two yokes 36 adjacent in the direction parallel to the X direction and the end in the −X direction of the other of the two yokes 36 when viewed in the Z direction. Some others of the plurality of first additional magnetic bodies 61A are located to overlap the end of a yoke 36 in the X direction or the −X direction when viewed in the Z direction.

In the present example embodiment, each of the plurality of second additional magnetic bodies 61B is located to overlap the end in the X direction of one of two yokes 36 adjacent in the direction parallel to the X direction and the end in the −X direction of the other of the two yokes 36 when viewed in the Z direction.

The number of yokes 36 will be represented by N (N is an integer greater than or equal to 4). The sum of the number of first additional magnetic bodies 61A and the number of second additional magnetic bodies 61B is less than 2N.

The configuration, operation, and effects of the present example embodiment are otherwise the same as those of the fourth or sixth example embodiment.

### Tenth Example Embodiment

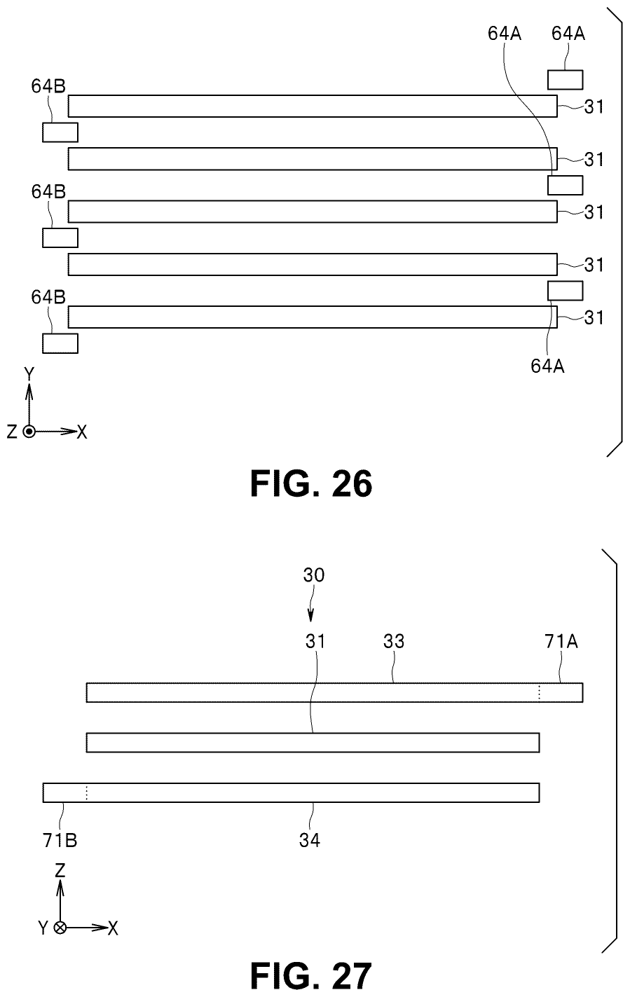

Next, a tenth example embodiment of the technology will be described with reference to FIG. 26. FIG. 26 is a plan view showing a plurality of yokes and a plurality of additional magnetic bodies according to the present example embodiment.

Differences of a soft magnetic structure 30 according to the present example embodiment from that of the sixth example embodiment will be described below. In the present example embodiment, the soft magnetic structure 30 includes a plurality of first additional magnetic bodies 64A and a plurality of second additional magnetic bodies 64B instead of the plurality of first additional magnetic bodies 61A and the plurality of second additional magnetic bodies 61B of the sixth example embodiment. As shown in FIG. 26, each of the plurality of first additional magnetic bodies 64A and each of the plurality of second additional magnetic bodies 64B are arranged next to a corresponding yoke 31 in the direction parallel to the X direction.

Each of the plurality of first additional magnetic bodies 64A is located near the end of a corresponding yoke 31 in the X direction. As shown in FIG. 26, each of the plurality of first additional magnetic bodies 64A is located off the corresponding yoke 31 in the direction parallel to the Y direction. In particular, in the present example embodiment, each of the plurality of first additional magnetic bodies 64A is located forward in the Y direction of the end in the X direction of one of two yokes 31 adjacent in the Y direction.

Each of the plurality of second additional magnetic bodies 64B is located near the end of a corresponding yoke 31 in the −X direction. As shown in FIG. 26, each of the plurality of second additional magnetic bodies 64B is located off the corresponding yoke 31 in the direction parallel to the Y direction. In particular, in the present example embodiment, each of the plurality of second additional magnetic bodies 64B is located forward in the −Y direction of the end in the −X direction of one of two yokes 31 adjacent in the Y direction.

The plurality of first additional magnetic bodies 64A and the plurality of second additional magnetic bodies 64B are located to satisfy the following first and second requirements. The first requirement is that, focusing on a yoke 31 with a first additional magnetic body 64A located forward in the Y direction of the end of this yoke 31 in the X direction, a second additional magnetic body 64B be located forward in the −Y direction of the end of this yoke 31 in the −X direction. The second requirement is that, focusing on a yoke 31 without a first additional magnetic body 64A located forward in the Y direction of the end of this yoke 31 in the X direction, a first additional magnetic body 64A be located forward in the −Y direction of the end of this yoke 31 in the X direction and a second additional magnetic body 64B be located forward in the Y direction of the end of this yoke 31 in the −X direction.

The yoke 31 focused on in the first requirement will be referred to as a first yoke, and the yoke 31 focused on in the second requirement will be referred to as a second yoke. The plurality of yokes 31 are arranged so that first yokes and second yokes alternate in the direction parallel to the Y direction.

The number of yokes 31 will be represented by N (N is an integer greater than or equal to 2). The sum of the number of first additional magnetic bodies 64A and the number of second additional magnetic bodies 64B is less than 2N.

In the present example embodiment, like the third example embodiment, an external magnetic field in a direction parallel to the Y direction is always applied to the magnetic sensor 1 in addition to the magnetic field to be detected. A case where an external magnetic field in the Y direction is applied to the magnetic sensor 1 will be described below as an example. In such a case, the external magnetic field in the Y direction is applied to the plurality of yokes 31, the plurality of first additional magnetic bodies 64A, and the plurality of second additional magnetic bodies 64B.

A first additional magnetic body 64A is located forward in the Y direction of the end of the first yoke in the X direction. A second additional magnetic body 64B is located forward in the −Y direction of the end of the first yoke in the −X direction. When the external magnetic field in the Y direction is applied to the first yoke, the first additional magnetic body 64A, and the second additional magnetic body 64B, a path for a magnetic flux to pass through is formed in a direction from the second additional magnetic body 64B to the first additional magnetic body 64A via the first yoke, and the first yoke is magnetized in the passing direction of the magnetic flux, i.e., the X direction.

A first additional magnetic body 64A is located forward in the −Y direction of the end of the second yoke in the X direction. A second additional magnetic body 64B is located forward in the Y direction of the end of the second yoke in the −X direction. When the external magnetic field in the Y direction is applied to the second yoke, the first additional magnetic body 64A, and the second additional magnetic body 64B, a path for a magnetic flux to pass through is formed in a direction from the first additional magnetic body 64A to the second additional magnetic body 64B via the second yoke, and the second yoke is magnetized in the passing direction of the magnetic flux, i.e., the −X direction.

In the present example embodiment, like the third example embodiment, the plurality of yokes 31 are arranged so that yokes 31 magnetized in the X direction and yokes 31 magnetized in the −X direction alternate in the direction parallel to the Y direction. According to the present example embodiment, the magnetization of the yokes 31 can be stabilized for the same reason as described in the third example embodiment. As a result, according to the present example embodiment, a change in the characteristics of the magnetic sensor 1 due to a change in the magnetization directions of the yokes 31 can be prevented.

The configuration, operation, and effects of the present example embodiment are otherwise the same as those of the third or sixth example embodiment.

### Eleventh Example Embodiment

Next, an eleventh example embodiment of the technology will be described with reference to FIG. 27. FIG. 27 is a side view showing a soft magnetic structure according to the present example embodiment.

Differences of a soft magnetic structure 30 according to the present example embodiment from that of the first example embodiment will be described below. In the present example embodiment, the soft magnetic structure 30 includes a first additional magnetic body 71A and a second additional magnetic body 71B instead of the plurality of first additional magnetic bodies 32A and the plurality of second additional magnetic bodies 32B according to the first example embodiment. Each of the first and second additional magnetic bodies 71A and 71B has a rectangular solid shape, for example. As shown in FIG. 27, the first additional magnetic body 71A and the second additional magnetic body 71B are arranged next to a plurality of yokes 31 in the direction parallel to the X direction.

The first additional magnetic body 71A is located near the ends of the plurality of yokes 31 in the X direction. In addition, the first additional magnetic body 71A is located forward of the plurality of yokes 31 in the Z direction. In particular, in the present example embodiment, the first additional magnetic body 71A is connected to the end of the shield 33 in the X direction. In FIG. 27, the border between the shield 33 and the first additional magnetic body 71A is shown in a dotted line. The shield 33 and the first additional magnetic body 71A may be formed of the same magnetic material.

The second additional magnetic body 71B is located near the ends of the plurality of yokes 31 in the −X direction. In addition, the second additional magnetic body 71B is located forward of the plurality of yokes 31 in the −Z direction. In particular, in the present example embodiment, the second additional magnetic body 71B is connected to the end of the shield 34 in the −X direction. In FIG. 27, the border between the shield 34 and the second additional magnetic body 71B is shown in a dotted line. The shield 34 and the second additional magnetic body 71B may be formed of the same magnetic material.

The first additional magnetic body 71A and the second additional magnetic body 71B are located so that at least a part of each of the plurality of yokes is interposed between the first additional magnetic body 71A and the second additional magnetic body 71B. A first magnetic body including the shield 33 and the first additional magnetic body 71A is located off a second magnetic body including the shield 34 and the second additional magnetic body 71B in the X direction.

In the present example embodiment, when an external magnetic field in the Z direction is applied to the plurality of yokes 31, the first additional magnetic body 71A, and the second additional magnetic body 71B, paths for a magnetic flux to pass through are formed in a direction from the second additional magnetic body 71B to the first additional magnetic body 71A via the plurality of yokes 31, and the plurality of yokes 31 are magnetized in the passing direction of the magnetic flux, i.e., the X direction.

The configuration, operation, and effects of the present example embodiment are otherwise the same as those of the first example embodiment.

### Twelfth Example Embodiment

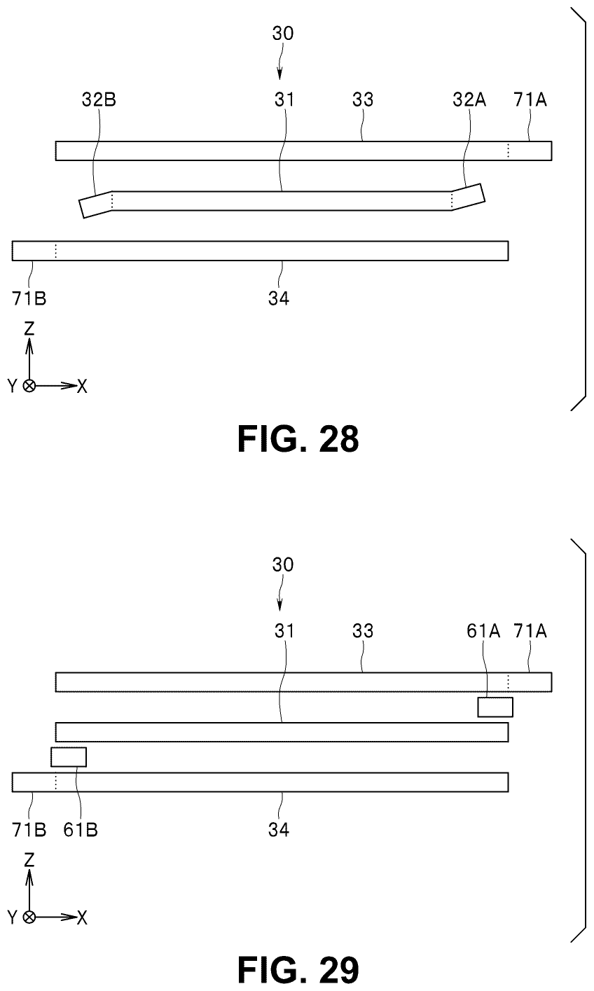

Next, a twelfth example embodiment of the technology will be described with reference to FIG. 28. FIG. 28 is a side view showing a soft magnetic structure according to the present example embodiment.

Differences of a soft magnetic structure 30 of the present example embodiment from that of the first example embodiment will be described below. In the present example embodiment, the soft magnetic structure 30 includes the first additional magnetic body 71A and the second additional magnetic body 71B of the eleventh example embodiment in addition to the plurality of first additional magnetic bodies 32A and the plurality of second additional magnetic bodies 32B of the first example embodiment.

The configuration, operation, and effects of the present example embodiment are otherwise the same as those of the first or eleventh example embodiment.

### Thirteenth Example Embodiment

Next, a thirteenth example embodiment of the technology will be described with reference to FIG. 29. FIG. 29 is a side view showing a soft magnetic structure according to the present example embodiment.

Differences of a soft magnetic structure 30 according to the present example embodiment from that of the sixth example embodiment will be described below. In the present example embodiment, the soft magnetic structure 30 includes the first additional magnetic body 71A and the second additional magnetic body 71B of the eleventh example embodiment in addition to the plurality of first additional magnetic bodies 61A and the plurality of second additional magnetic bodies 61B of the sixth example embodiment.

The configuration, operation, and effects of the present example embodiment are otherwise the same as those of the sixth or eleventh example embodiment.

The technology is not limited to the foregoing example embodiments, and various modifications can be made. For example, the configuration of the soft magnetic structure 30 is not limited to the examples described in the example embodiments, and such configurations can be freely combined as long as the requirements of the appended claims are met.

As has been described above, a magnetic sensor of the technology includes: a soft magnetic structure including at least one yoke having a shape long in one direction; and a magnetic detection element configured to detect a magnetic field generated by the at least one yoke, the magnetic detection element being adjacent to the at least one yoke in a transverse direction of the at least one yoke. The soft magnetic structure further includes at least one additional magnetic body arranged next to the at least one yoke in a longitudinal direction of the at least one yoke and located off the at least one yoke in an orthogonal direction orthogonal to the longitudinal direction of the at least one yoke.

In the magnetic sensor according to the technology, the at least one additional magnetic body may include a first additional magnetic body located off the at least one yoke in a first direction that is a direction parallel to the orthogonal direction, and a second additional magnetic body located off the at least one yoke in a second direction opposite to the first direction. In other words, the at least one additional magnetic body may be at least two additional magnetic bodies.

In the magnetic sensor according to the technology, the at least one additional magnetic body may be connected to the at least one yoke.

In the magnetic sensor according to the technology, the at least one additional magnetic body may be located at a distance from the at least one yoke.

In the magnetic sensor according to the technology, the soft magnetic structure may further include a shield located off the at least one yoke in the orthogonal direction. The at least one additional magnetic body may be connected to the shield.

In the magnetic sensor according to the technology, the at least one yoke may include a plurality of yokes. In other words, the at least one yoke may be a plurality of yokes. The at least one additional magnetic body may include a plurality of additional magnetic bodies. In other words, the at least one additional magnetic body may be a plurality of additional magnetic bodies.

If the at least one yoke is a plurality of yokes and the at least one additional magnetic body is a plurality of additional magnetic bodies, the plurality of yokes may include a first yoke and a second yoke located to be adjacent to each other in the transverse direction. The plurality of additional magnetic bodies may include a first additional magnetic body arranged next to the first yoke in the longitudinal direction and located off the first yoke in a first direction that is a direction parallel to the orthogonal direction, a second additional magnetic body located with at least a part of the first yoke interposed between the first additional magnetic body and the second additional magnetic body and located off the first yoke in a second direction opposite to the first direction, a third additional magnetic body arranged next to the second yoke in the longitudinal direction and located off the second yoke in the first direction, and a fourth additional magnetic body located with at least a part of the second yoke interposed between the third additional magnetic body and the fourth additional magnetic body and located off the second yoke in the second direction. The first additional magnetic body and the fourth additional magnetic body may be adjacent to each other in the transverse direction. The second additional magnetic body and the third additional magnetic body may be adjacent to each other in the transverse direction.

If the at least one yoke is a plurality of yokes and the at least one additional magnetic body is a plurality of additional magnetic bodies, the number of yokes may be N and the number of additional magnetic bodies may be less than or equal to 2N, where N is an integer greater than or equal to 2.

If the at least one yoke is a plurality of yokes and the at least one additional magnetic body is a plurality of additional magnetic bodies, the soft magnetic structure may further include a shield located off the at least one yoke in the orthogonal direction. The plurality of additional magnetic bodies may include a first additional magnetic body connected to the shield and a second additional magnetic body not connected to the shield.

In the magnetic sensor according to the technology, the at least one yoke may include two yokes adjacent in the longitudinal direction. In other words, the at least one yoke may be at least two yokes.

The magnetic sensor according to the technology may further include a magnetic field generator configured to have a magnetization in a direction parallel to the orthogonal direction and generate a magnetic field to be applied to the at least one yoke.

A position detection device according to the technology includes: the magnetic sensor of the technology; and a magnetic field generator configured to have a magnetization in a direction parallel to the orthogonal direction and generate a magnetic field to be applied to the at least one yoke. The magnetic sensor and the magnetic field generator are configured to change their relative position in the orthogonal direction and so that a strength of the magnetic field changes with a change in the relative position.

A lens module of the technology includes: a lens configured to change in position; the magnetic sensor of the technology; and a magnetic field generator configured to have a magnetization in a direction parallel to the orthogonal direction and generate a magnetic field to be applied to the at least one yoke. The magnetic sensor and the magnetic field generator are configured so that a strength of the magnetic field changes with a change in the position of the lens.

According to one embodiment of the technology, the soft magnetic structure includes the at least one yoke and the at least one additional magnetic body located off the at least one yoke in the orthogonal direction. According to one embodiment of the technology, a magnetic sensor capable of preventing a change in its output characteristics due to the at least one yoke, and a position detection device and a lens module each including the magnetic sensor can thus be achieved.

Obviously, many modifications and variations of the technology are possible in the light of the above teachings. Thus, it is to be understood that, within the scope of the appended claims and equivalents thereof, the technology may be practiced in other example embodiments than the foregoing example embodiments.

What is claimed is:

1. A magnetic sensor comprising:
a soft magnetic structure including at least one yoke having a shape long in one direction; and
a magnetic detection element configured to detect a magnetic field generated by the at least one yoke, the magnetic detection element being adjacent to the at least one yoke in a transverse direction of the at least one yoke, wherein
the soft magnetic structure further includes at least one additional magnetic body arranged next to the at least one yoke in a longitudinal direction of the at least one yoke and located off the at least one yoke in an orthogonal direction orthogonal to the longitudinal direction.

2. The magnetic sensor according to claim 1, wherein the at least one additional magnetic body includes a first additional magnetic body located off the at least one yoke in a first direction that is a direction parallel to the orthogonal direction, and a second additional magnetic body located off the at least one yoke in a second direction opposite to the first direction.

3. The magnetic sensor according to claim 1, wherein the at least one additional magnetic body is connected to the at least one yoke.

4. The magnetic sensor according to claim 1, wherein the at least one additional magnetic body is located at a distance from the at least one yoke.

5. The magnetic sensor according to claim 1, wherein:
the soft magnetic structure further includes a shield located off the at least one yoke in the orthogonal direction; and
the at least one additional magnetic body is connected to the shield.

6. The magnetic sensor according to claim 1, wherein:
the at least one yoke includes a plurality of yokes; and
the at least one additional magnetic body includes a plurality of additional magnetic bodies.

7. The magnetic sensor according to claim 6, wherein:
the plurality of yokes include a first yoke and a second yoke located to be adjacent to each other in the transverse direction;
the plurality of additional magnetic bodies include
a first additional magnetic body arranged next to the first yoke in the longitudinal direction and located off the first yoke in a first direction that is a direction parallel to the orthogonal direction,
a second additional magnetic body located with at least a part of the first yoke interposed between the first additional magnetic body and the second additional magnetic body and located off the first yoke in a second direction opposite to the first direction,
a third additional magnetic body arranged next to the second yoke in the longitudinal direction and located off the second yoke in the first direction, and
a fourth additional magnetic body located with at least a part of the second yoke interposed between the third additional magnetic body and the fourth additional magnetic body and located off the second yoke in the second direction;
the first additional magnetic body and the fourth additional magnetic body are adjacent to each other in the transverse direction; and
the second additional magnetic body and the third additional magnetic body are adjacent to each other in the transverse direction.

8. The magnetic sensor according to claim 6, wherein the number of yokes is N and the number of additional magnetic bodies is less than or equal to 2N, where N is an integer greater than or equal to 2.

9. The magnetic sensor according to claim 6, wherein:
the soft magnetic structure further includes a shield located off the at least one yoke in the orthogonal direction; and
the plurality of additional magnetic bodies include a first additional magnetic body connected to the shield and a second additional magnetic body not connected to the shield.

10. The magnetic sensor according to claim 1, wherein the at least one yoke includes two yokes adjacent in the longitudinal direction.

11. The magnetic sensor according to claim 1, further comprising a magnetic field generator configured to have a magnetization in a direction parallel to the orthogonal direction and generate a magnetic field to be applied to the at least one yoke.

12. A position detection device comprising:
the magnetic sensor according to claim 1; and
a magnetic field generator configured to have a magnetization in a direction parallel to the orthogonal direction and generate a magnetic field to be applied to the at least one yoke, wherein
the magnetic sensor and the magnetic field generator are configured to change their relative position in the orthogonal direction and so that a strength of the magnetic field changes with a change in the relative position.

13. A lens module comprising:
a lens configured to change in position;
the magnetic sensor according to claim 1; and
a magnetic field generator configured to have a magnetization in a direction parallel to the orthogonal direction and generate a magnetic field to be applied to the at least one yoke, wherein
the magnetic sensor and the magnetic field generator are configured so that a strength of the magnetic field changes with a change in a position of the lens.
